(19) United States
(12) Patent Application Publication
(10) Pub. No.: US 2008/0116528 A1
(43) Pub. Date: May 22, 2008

(54) SEMICONDUCTOR DEVICE AND METHOD OF MANUFACTURING THE SAME

(76) Inventors: Tsuneichiro SANO, Toyama (JP); Osamu MATSUI, Kyoto (JP); Shuji TSUJINO, Kyoto (JP)

Correspondence Address: MCDERMOTT WILL & EMERY LLP, 600 13TH STREET, NW, WASHINGTON, DC, 20005-3096, US

(21) Appl. No.: 11/939,864

(22) Filed: Nov. 14, 2007

(30) Foreign Application Priority Data
Nov. 22, 2006 (JP) 2006-315528
Sep. 18, 2007 (JP) 2007-240555

(51) Int. Cl. H01L 21/8234; H01L 27/088

(52) U.S. Cl. 257/392; 438/275; 257/E21.616; 257/E27.06

(57) ABSTRACT

A semiconductor device according to the present invention comprises a semiconductor substrate of a first conductive type, a first element region and a second element region provided on the semiconductor substrate, a retrograde well formed from a first impurity of a second conductive type and provided at a deep section, in a thickness direction, of the first element region, an enhanced dope layer formed from a second impurity of the second conductive type and provided at an intermediate section, in a thickness direction, of the first element region, a punch-through control layer formed from a third impurity of the second conductive type and provided at a surface section of the first element region, a second gate insulation film provided on the semiconductor substrate and making contact with the first element region, and a first gate insulation film provided on the semiconductor substrate, making contact with the second element region and having a thickness larger than that of the second gate insulation film, wherein the second impurity is distributed in a region where a profile of the first impurity and a profile of the third impurity intersect with each other.

### BACKGROUND OF THE INVENTION

1. Field of the Invention

The present invention relates to a semiconductor device and a method of manufacturing the semiconductor device, more particularly to a semiconductor device having two or more different kinds of gate oxide films; namely, a semiconductor device in which a so-called high-voltage MOSFET and a so-called low-voltage MOSFET coexist, and a method of manufacturing the semiconductor device.

2. Description of the Related Art

As the system-on-chip has been increasingly demanded, a CMOS integrated circuit, which comprises a plurality of MOSFETs (for example, a high-voltage MOSFET and a low-voltage MOSFET each a comprising gate oxide film having a thickness different to each other) on one chip, has been commercialized. This technology is recited in, for example, No. 2006-196580 and No. 2003-46062 of the Japanese Patent Laid-Open.

As the reduction of power consumption and miniaturization process have been increasingly advanced in the semiconductor integrated circuit in recent years, the development of such a CMOS integrated circuit that comprises the low-voltage MOSFET which emphasizes an analog characteristic and the high-voltage MOSFET used in an input/output circuit or the like on the same substrate is underway.

Below is described a conventional method of manufacturing a semiconductor device provided with the low-voltage MOSFET and the high-voltage MOSFET referring to FIGS. 43-52 which shows sectional views of the manufacturing process. First, as shown in FIG. 43, element isolation insulation films 102a and 102b and a silicon oxide film 105 are formed on a p-type silicon substrate 101. Next, n-type diffusion layers 103a and 103b and p-type diffusion layers 104a and 104b are formed on the p-type silicon substrate 101. The n-type diffusion layers 103a and 103b and p-type diffusion layers 104a and 104b constitute a CMOS well. After that, p-type diffusion layers 106a and 106b for controlling a surface impurity concentration of the p-type MOSFET are formed on the p-type silicon substrate 101.

Next, the silicon oxide film 105 is removed from the p-type silicon substrate 101 as shown in FIG. 44, and a gate oxide film 107 for the high-voltage MOSFET is formed on the p-type silicon substrate 101 as shown in FIG. 45. Next, as shown in FIG. 46, a photo resist 108 is applied to the p-type silicon substrate 101, and an opening is formed in the photo resist 108 in the low-voltage MOSFET region. Then, as shown in FIG. 47, the high-voltage gate oxide film 107 is etched with the photo resist 108 having the opening being used as a mask.

Next, as shown in FIG. 48, the photoresist 108 is removed, and then, a gate oxide film 109 for the low-voltage MOSFET is formed on the p-type silicon substrate 101. Then, as shown in FIG. 49, an n-type polysilicon film 110 is grown on the p-type silicon substrate 101. Next, as shown in FIG. 50, a photoresist, not shown, is used as the mask so that the n-type polysilicon film is etched. Polysilicon films 110′ are thereby formed, and then, a side wall 111 is formed on a side surface of each of the polysilicon films 110′.

Next, as shown in FIG. 51, a photo resist, not shown, is used as the mask so that impurity ions are implanted into the p-type silicon substrate 101. Then, a heat treatment is applied to the p-type silicon substrate 101 so that sources and drains 112a and 112b of the n-type MOSFET and sources and drains 113a and 113b of the p-type MOSFET are formed. Finally, as shown in FIG. 52, inter-layer insulation films 114 (each comprising an oxide silicon film and a BPSG film), W plugs 115 and AL electrodes 116 are formed on the p-type silicon substrate 101.

In the method of manufacturing the conventional semiconductor device shown in FIGS. 43-52, the high-voltage gate oxide film 107 is formed also in the low-voltage MOSFET region. Therefore, the formed oxide film fetches the surface impurities thereinto, which reduces the surface impurity concentration of the low-voltage MOSFET region.

A conventional solution for compensating for the reduction of the surface impurity concentration is that a large quantity of impurity ions are implanted in advance, which, however, creates a phenomenon (going deep) in which the impurity is formed through to positions down below in the processes of the ion implantation and activation annealing. In the case where the amount of the implanted impurities is increased in order to compensate for the reduction of a boron concentration in the surface impurities, particularly, in the p-type MOSFET, the n-type impurity concentration on the bulk side is reduced since the boron is formed down below, and an early voltage is thereby reduced.

### SUMMARY OF THE INVENTION

Therefore, a main object of the present invention is to control the reduction of an early voltage in a CMOS integrated circuit where a high-voltage MOSFET and a low-voltage MOSFET coexist on one chip.

A semiconductor device according to the present invention is a semiconductor device comprising at least two MOSFETs each comprising a gate insulation film having a thickness different to each other, further comprising:

a semiconductor substrate of a first conductive type;

a first element region and a second element region provided on the semiconductor substrate;

a retrograde well formed from a first impurity of a second conductive type and provided at a deep section, in a thickness direction, of the first element region;

an enhanced dope layer formed from a second impurity of the second conductive type and provided at an intermediate section, in a thickness direction, of the first element region;

a punch-through control layer formed from a third impurity of the second conductive type and provided at a surface section of the first element region;

a second gate insulation film provided on the semiconductor substrate and making contact with the first element region; and

a first gate insulation film provided on the semiconductor substrate, making contact with the second element region and having a thickness larger than that of the second gate insulation film, wherein

the second impurity is distributed in a region where a profile of the first impurity and a profile of the third impurity intersect with each other.

A method of manufacturing a semiconductor device according to the present invention is a method of manufacturing a semiconductor device comprising at least two MOSFETs each comprising a gate insulation film having a thickness different to each other, including:

a step of forming a first element region and a second element region on a semiconductor substrate of a first conductive type;

a step of ion-implanting a first impurity of a second conductive type at a deep section, in a thickness direction, of the first element region, a second impurity of the second conductive type at an intermediate section, in a thickness direction, of the first element region, and a third impurity of the second conductive type at a surface section of the first element region;

a step of forming a first gate insulation film on the semiconductor substrate including the first and second element regions after the first through third impurities are ion-implanted;

a step of selectively removing the first gate insulation film from the first element region and thereafter selectively forming a second insulation film in the first element region; and

a step of forming a gate electrode on the respective first and second gate insulation films, wherein

the first through third impurities are ion-implanted so that the second impurity is distributed in a region where a profile of the first impurity and a profile of the third impurity intersect with each other.

According to the method of manufacturing the semiconductor device wherein the second impurity is distributed in the region where the profile of the first impurity and the profile of the third impurity intersect with each other, a surface impurity concentration for controlling a threshold value is prevented from increasing, while an impurity concentration on the bulk side can be increased at the same time. As a result, the reduction of an early voltage can be controlled.

A method of manufacturing a semiconductor device according to the present invention may be constituted as follows. A method of manufacturing a semiconductor device according to the present invention is a method of manufacturing a semiconductor device comprising at least two MOSFETs each comprising a gate insulation film having a thickness different to each other, including:

a step of forming a first element region and a second element region on a semiconductor substrate of a first conductive type;

a step of ion-implanting an impurity of a second conductive type inside the first element region and an impurity of the first conductive type at a surface section of the first element region;

a step of selectively forming a first gate insulation film in the second element region and a second gate insulation film in the first element region after the impurities are ion-implanted; and

a step of forming a gate electrode on the respective first and second gate insulation films, wherein

a p-type MOSFET of an embedding channel type is formed in the first element region.

According to the method of manufacturing the semiconductor device, when the first gate insulation film for the high-voltage MOSFEDT is formed, for example, the reduction of the concentration of the surface impurity in the first element region for the low-voltage MOSFEDT is prevented. Therefore, a dose amount for the surface impurity concentration for controlling the threshold value can be reduced in comparison to such a case that the reduction of the concentration occurs. As a result, the surface impurity is not formed at any deep section, and the reduction of the early voltage can be controlled.

The step of selectively forming the first gate insulation film preferably includes:

a step of selectively forming a silicon nitride film in the respective first and second element regions;

a step of selectively removing the silicon nitride film formed in the second element region; and

a step of selectively forming the first gate insulation film in the second element region and thereafter selectively removing the silicon nitride film formed in the first element region.

According to the foregoing constitution, the formation of the first gate insulation film (for example, used for the high-voltage MOSFET) in the first element region (for example, used for the low-voltage MOSFET) is intentionally avoided so that the surface impurity in the first element region is not fetched into the oxide film when the first gate insulation film is formed. Accordingly, the reduction of the surface impurity concentration can be controlled, and the dose amount for the surface impurity concentration for controlling the threshold value can be reduced in comparison to such a case that the reduction of the concentration occurs. As a result, the surface impurity is not formed at any deep section, and the reduction of the early voltage can be thereby controlled.

The step of selectively forming the first gate insulation film preferably includes:

a step of selectively forming a polysilicon film in the respective first and second element regions;

a step of selectively removing the polysilicon film formed in the second element region; and

a step of selectively forming the first gate insulation film in the second element region and thereafter selectively removing the polysilicon film formed in the first element region.

According to the foregoing constitution, the formation of the first gate insulation film (for example, used for the high-voltage MOSFET) in the first element region (for example, used for the low-voltage MOSFET) is intentionally avoided so that the surface impurity in the first element region is not fetched into the oxide film when the first gate insulation film is formed. Accordingly, the reduction of the surface impurity concentration can be controlled, and the dose amount for the surface impurity concentration for controlling the threshold value can be reduced in comparison to such a case that the reduction of the concentration occurs. As a result, the surface impurity is not formed at any deep section, and the reduction of the early voltage can be thereby controlled.

The step of selectively forming the first gate insulation film preferably includes:

a step of selectively forming the first gate insulation film in the respective first and second element regions; and

a step of selectively removing the first gate insulation film formed in the first element region, wherein

the step of forming the first gate insulation film is implemented before the impurity of the first conductive type is ion-implanted.

According to the foregoing constitution, the ions for controlling the threshold voltage for the low-voltage MOSFET are implanted after the first gate insulation film, for example, for the high-voltage MOSFET, is formed. Accordingly, the reduction of the surface impurity concentration for controlling the threshold voltage for the low-voltage MOSFET is prevented when the first gate insulation film is formed, and the dose amount for the surface impurity concentration for controlling the threshold value can be reduced in comparison to such a case that the reduction occurs. As a result, the surface impurity is not formed at any deep section, and the reduction of the early voltage can be thereby controlled.

According to the semiconductor device and the method of manufacturing the same wherein the enhanced dope layer is formed at the intermediate section, in the depth direction, of the low-voltage MOSFET region, the increase of the surface impurity concentration for controlling the threshold value can be controlled, while the impurity concentration on the bulk side can be increased at the same time. As a result, the reduction of the early voltage can be controlled.

Further, the reduction of the surface impurity concentration in the low-voltage MOSFET region at the time when the gate oxide film for the high-voltage MOSFET is formed can be controlled. Therefor, the dose amount for the surface impurity concentration for controlling the threshold value can be reduced. As a result, the reduction of the early voltage resulting from the surface impurity going deep can be controlled.

The present invention is effectively applied to a semiconductor device and a semiconductor device manufacturing method capable of controlling the reduction of an early voltage in a semiconductor integrated circuit in which a high-voltage MOSFET and a low-voltage MOSFET coexist on one chip.

### BRIEF DESCRIPTION OF THE DRAWINGS

These and other objects as well as advantages of the invention will become clear by the following description of preferred embodiments of the invention, and they are specified in the claims attached hereto. A number of benefits not recited in this specification will come to the attention of the skilled in the art upon the implementation of the present invention.

FIG. 1 is a sectional view illustrating a process of manufacturing a semiconductor device according to a preferred embodiment 1 of the present invention.

FIG. 2 is a sectional view illustrating the process of manufacturing the semiconductor device according to the preferred embodiment 1.

FIG. 3 is a sectional view illustrating the process of manufacturing the semiconductor device according to the preferred embodiment 1.

FIG. 4 is a sectional view illustrating the process of manufacturing the semiconductor device according to the preferred embodiment 1.

FIG. 5 is a sectional view illustrating the process of manufacturing the semiconductor device according to the preferred embodiment 1.

FIG. 6 is a sectional view illustrating the process of manufacturing the semiconductor device according to the preferred embodiment 1.

FIG. 7 is a sectional view illustrating the process of manufacturing the semiconductor device according to the preferred embodiment 1.

FIG. 8 is a sectional view illustrating the process of manufacturing the semiconductor device according to the preferred embodiment 1.

FIG. 9 is a sectional view illustrating the process of manufacturing the semiconductor device according to the preferred embodiment 1.

FIG. 10 is a sectional view illustrating the process of manufacturing the semiconductor device according to the preferred embodiment 1.

FIG. 11 is a sectional view illustrating the process of manufacturing the semiconductor device according to the preferred embodiment 1.

FIG. 12 is a sectional view illustrating a process of manufacturing a semiconductor device according to a modified embodiment of the preferred embodiment 1.

FIG. 13 is a sectional view illustrating the process of manufacturing the semiconductor device according to the modified embodiment of the preferred embodiment 1.

FIG. 14 is a sectional view illustrating the process of manufacturing the semiconductor device according to the modified embodiment of the preferred embodiment 1.

FIG. 15 is a sectional view illustrating the process of manufacturing the semiconductor device according to the modified embodiment of the preferred embodiment 1.

FIG. 16 is a sectional view illustrating the process of manufacturing the semiconductor device according to the modified embodiment of the preferred embodiment 1.

FIG. 17 is a sectional view illustrating the process of manufacturing the semiconductor device according to the modified embodiment of the preferred embodiment 1.

FIG. 18 is a sectional view illustrating a process of manufacturing a semiconductor device according to a preferred embodiment 2 of the present invention.

FIG. 19 is a sectional view illustrating the process of manufacturing the semiconductor device according to the preferred embodiment 2.

FIG. 20 is a sectional view illustrating the process of manufacturing the semiconductor device according to the preferred embodiment 2.

FIG. 21 is a sectional view illustrating the process of manufacturing the semiconductor device according to the preferred embodiment 2.

FIG. 22 is a sectional view illustrating the process of manufacturing the semiconductor device according to the preferred embodiment 2.

FIG. 23 is a sectional view illustrating the process of manufacturing the semiconductor device according to the preferred embodiment 2.

FIG. 24 is a sectional view illustrating the process of manufacturing the semiconductor device according to the preferred embodiment 2.

FIG. 25 is a sectional view illustrating the process of manufacturing the semiconductor device according to the preferred embodiment 2.

FIG. 26 is a sectional view illustrating the process of manufacturing the semiconductor device according to the preferred embodiment 2.

FIG. 27 is a sectional view illustrating the process of manufacturing the semiconductor device according to the preferred embodiment 2.

FIG. 28 is a sectional view illustrating the process of manufacturing the semiconductor device according to the preferred embodiment 2.

FIG. 29 is a sectional view illustrating the process of manufacturing the semiconductor device according to the preferred embodiment 2.

FIG. 30 is a sectional view illustrating a process of manufacturing a semiconductor device according to a preferred embodiment 3 of the present invention.

FIG. 31 is a sectional view illustrating the process of manufacturing the semiconductor device according to the preferred embodiment 3.

FIG. 32 is a sectional view illustrating the process of manufacturing the semiconductor device according to the preferred embodiment 3.

FIG. 33 is a sectional view illustrating the process of manufacturing the semiconductor device according to the preferred embodiment 3.

FIG. 34 is a sectional view illustrating the process of manufacturing the semiconductor device according to the preferred embodiment 3.

FIG. 35 is a sectional view illustrating the process of manufacturing the semiconductor device according to the preferred embodiment 3.

FIG. 36 is a sectional view illustrating the process of manufacturing the semiconductor device according to the preferred embodiment 3.

FIG. 37 is a sectional view illustrating the process of manufacturing the semiconductor device according to the preferred embodiment 3.

FIG. 38 is a sectional view illustrating the process of manufacturing the semiconductor device according to the preferred embodiment 3.

FIG. 39 is a sectional view illustrating the process of manufacturing the semiconductor device according to the preferred embodiment 3.

FIG. 40 is a sectional view illustrating the process of manufacturing the semiconductor device according to the preferred embodiment 3.

FIG. 41 shows an impurity profile of the semiconductor device according to the preferred embodiment 3.

FIGS. 42A and 42B show early voltage characteristics of the semiconductor device according to the preferred embodiment 3.

FIG. 43 is a sectional view illustrating a process of manufacturing a semiconductor device according to a conventional technology.

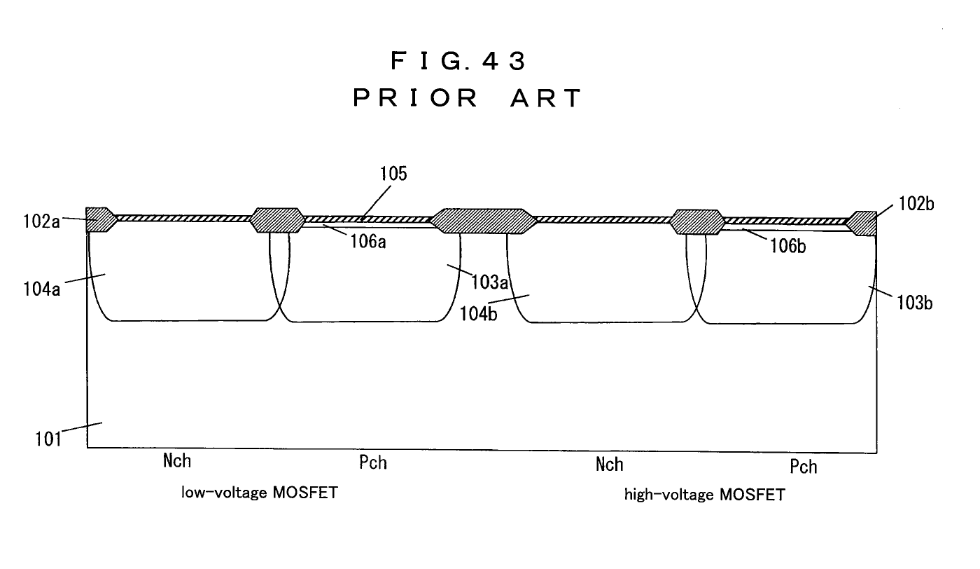

FIG. 44 is a sectional view illustrating the process of manufacturing the semiconductor device according to the conventional technology.

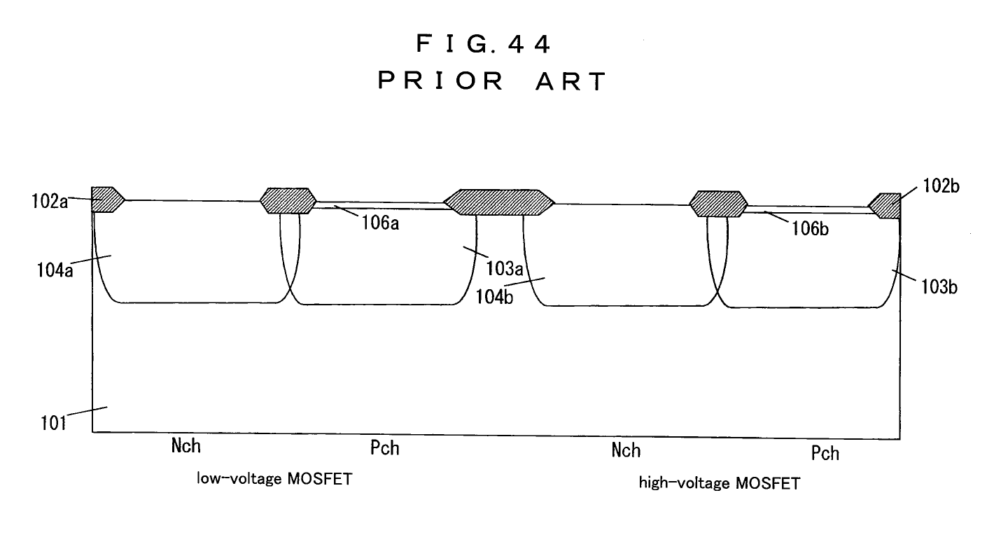

FIG. 45 is a sectional view illustrating the process of manufacturing the semiconductor device according to the conventional technology.

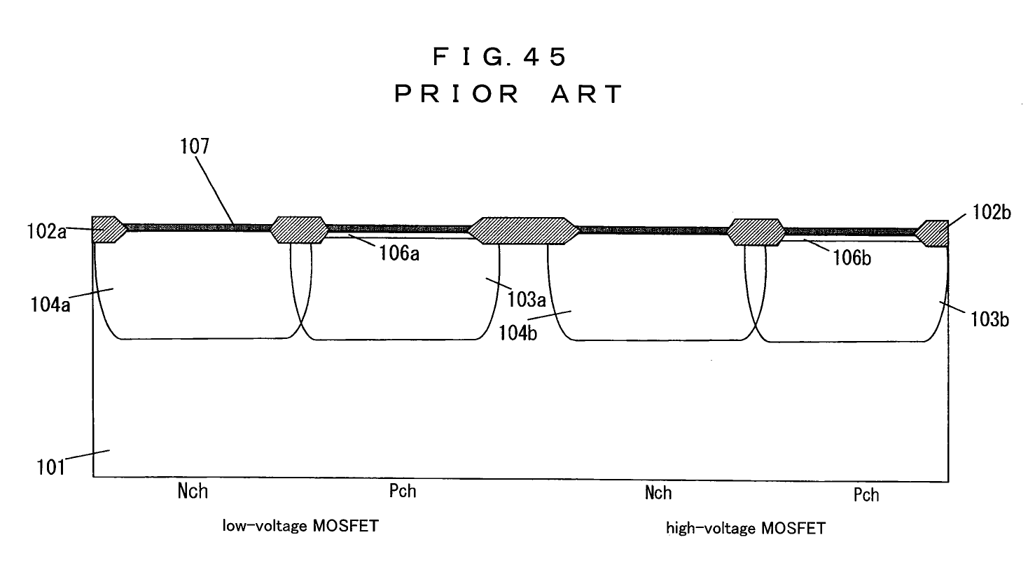

FIG. 46 is a sectional view illustrating the process of manufacturing the semiconductor device according to the conventional technology.

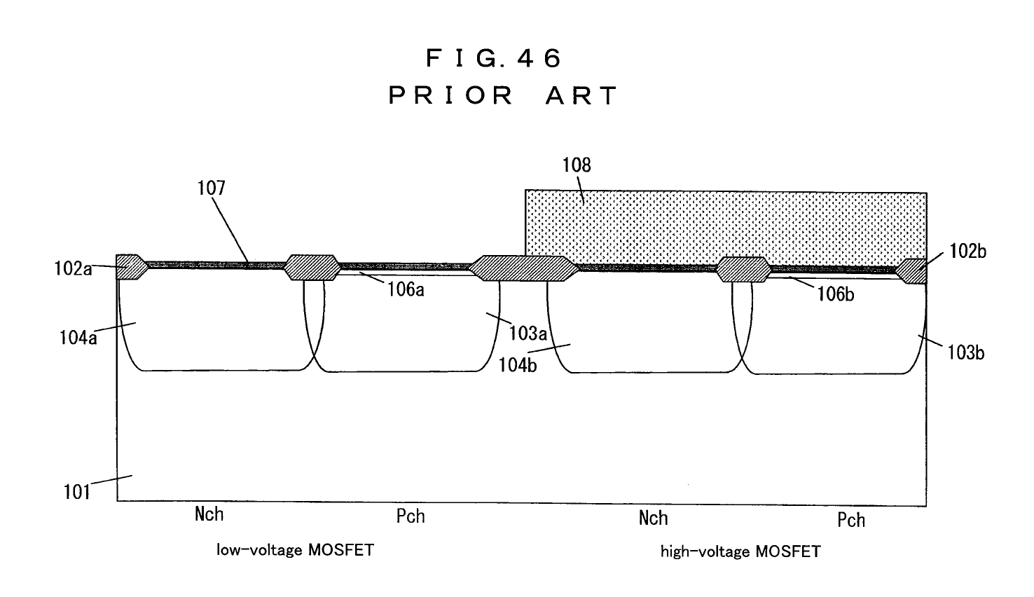

FIG. 47 is a sectional view illustrating the process of manufacturing the semiconductor device according to the conventional technology.

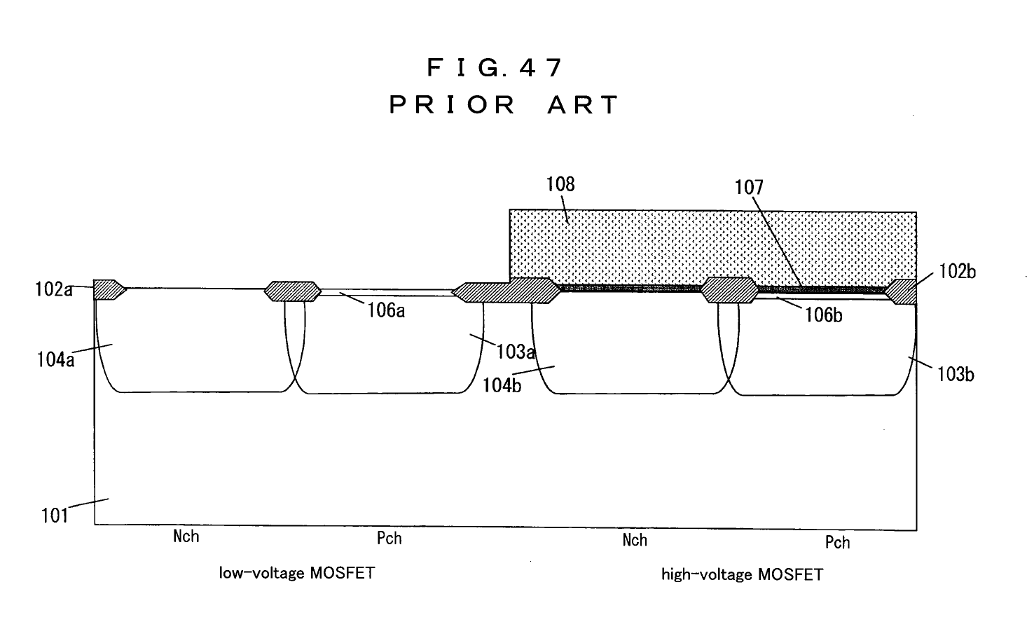

FIG. 48 is a sectional view illustrating the process of manufacturing the semiconductor device according to the conventional technology.

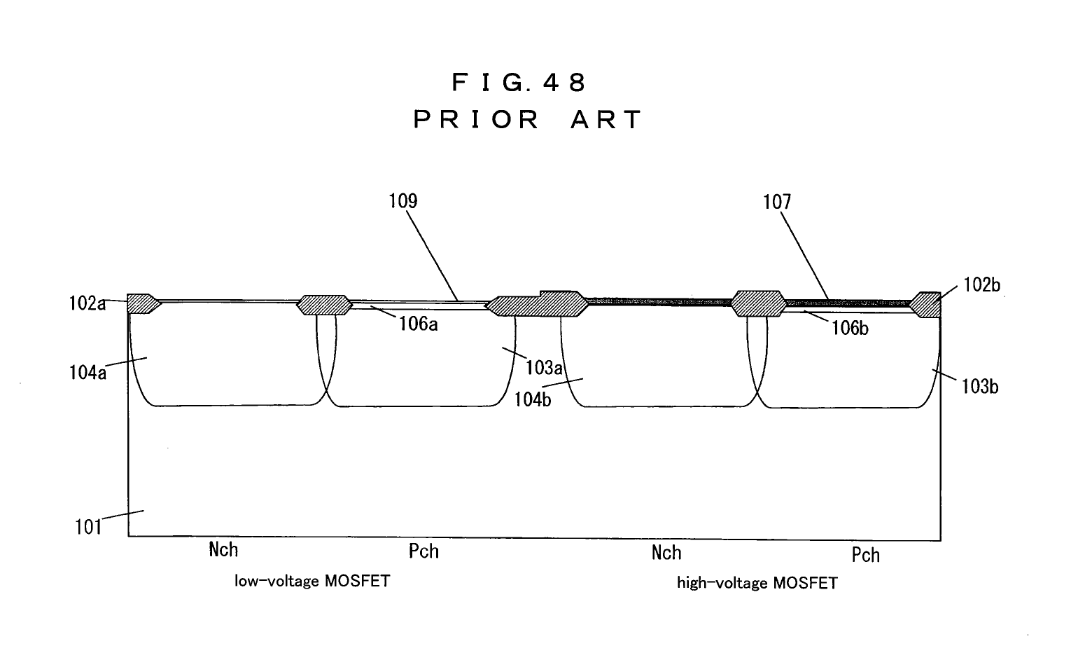

FIG. 49 is a sectional view illustrating the process of manufacturing the semiconductor device according to the conventional technology.

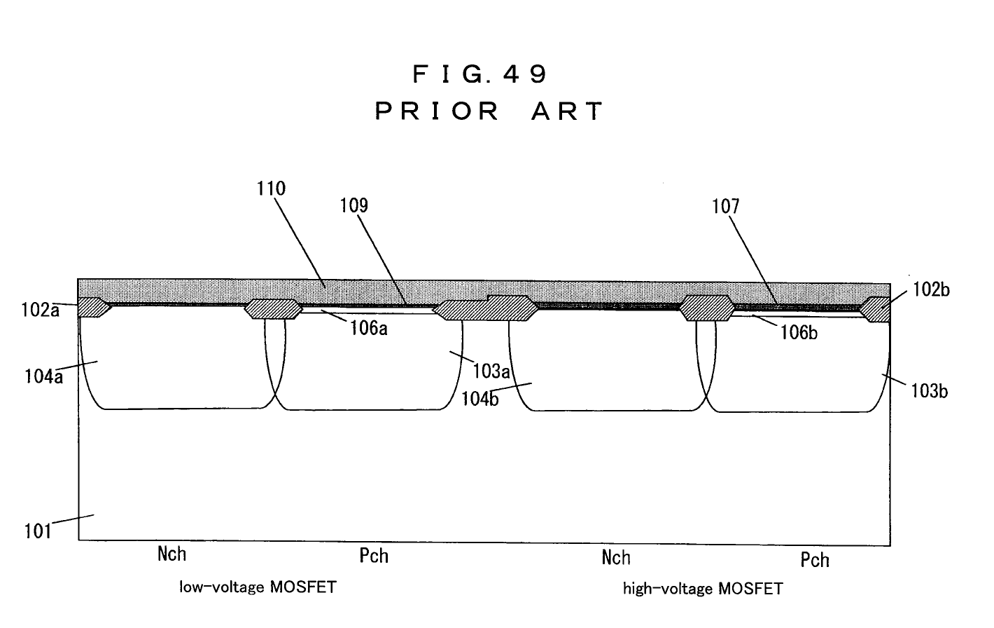

FIG. 50 is a sectional view illustrating the process of manufacturing the semiconductor device according to the conventional technology.

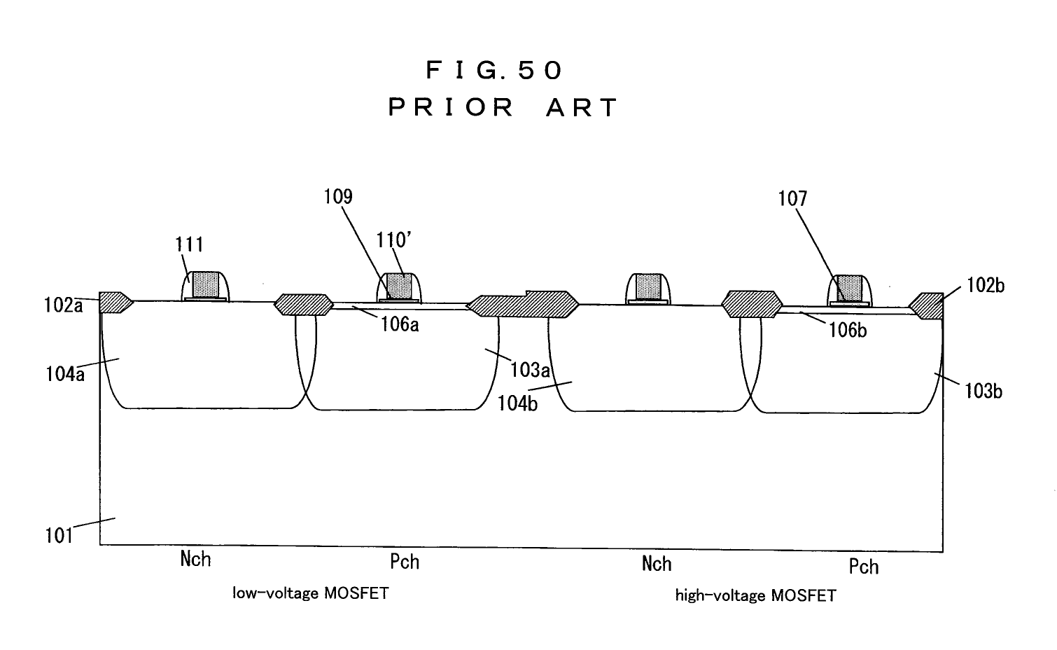

FIG. 51 is a sectional view illustrating the process of manufacturing the semiconductor device according to the conventional technology.

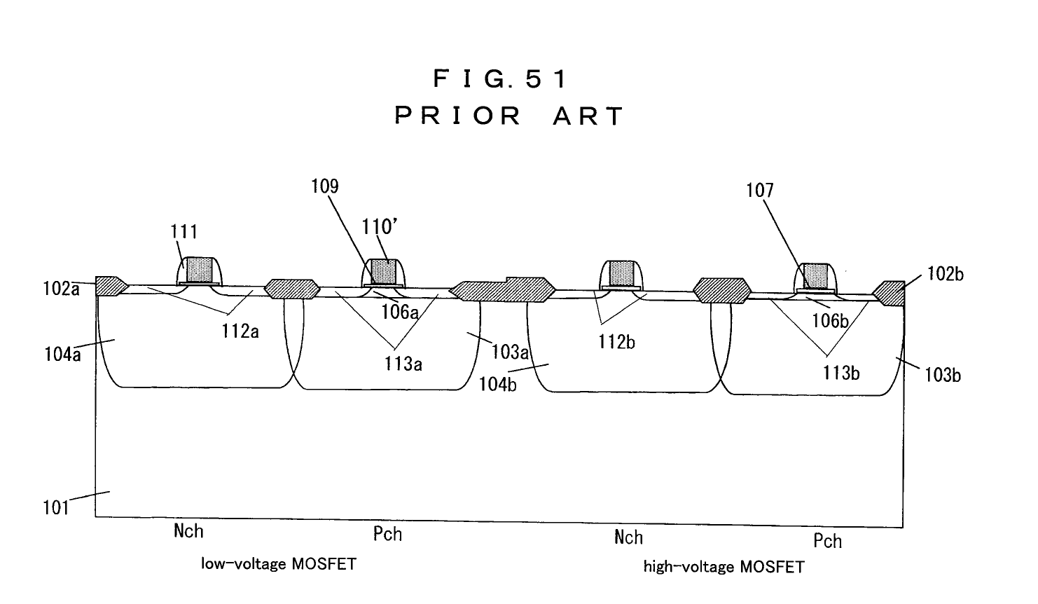

FIG. 52 is a sectional view illustrating the process of manufacturing the semiconductor device according to the conventional technology.

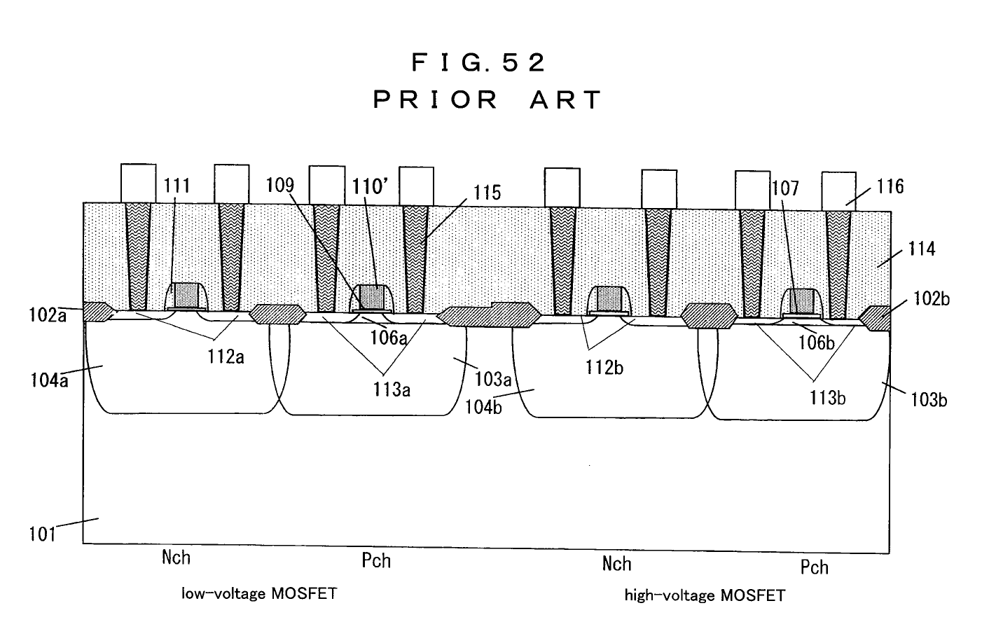

### DETAILED DESCRIPTION OF THE INVENTION

### Preferred Embodiment 1

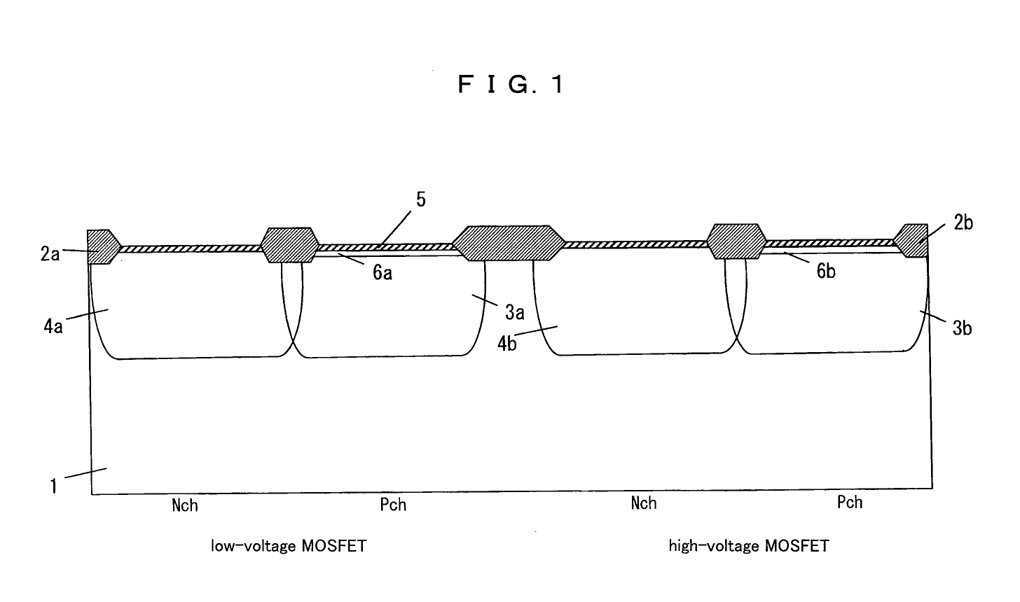

Hereinafter, a method of manufacturing a semiconductor device according to a preferred embodiment 1 of the present invention is described referring to FIGS. 1-11. In the drawings, a low-voltage MOSFET denotes an element formed in a first element region, while a high-voltage MOSFET denotes an element formed in a second element region. In the present preferred embodiment, a first conductive type is described as p type, and a second conductive type is described as n type. However, this is only an example, and the first conductive type may be described as the n type, and the second conductive type may be described as the p type.

First, as shown in FIG. 1, element isolation oxide films (element isolation insulation films) 2a and 2b and a silicon oxide film 5 are formed on a p-type silicon substrate (semiconductor substrate) 1. Next, n-type diffusion layers 3a and 3b and p-type diffusion layers 4a and 4b are formed on the p-type silicon substrate 1. These diffusion layers constitute a CMOS well. Further, p-type diffusion layers 6a and 6b for controlling a surface impurity concentration of the p-type MOSFET are formed on the p-type silicon substrate 1.

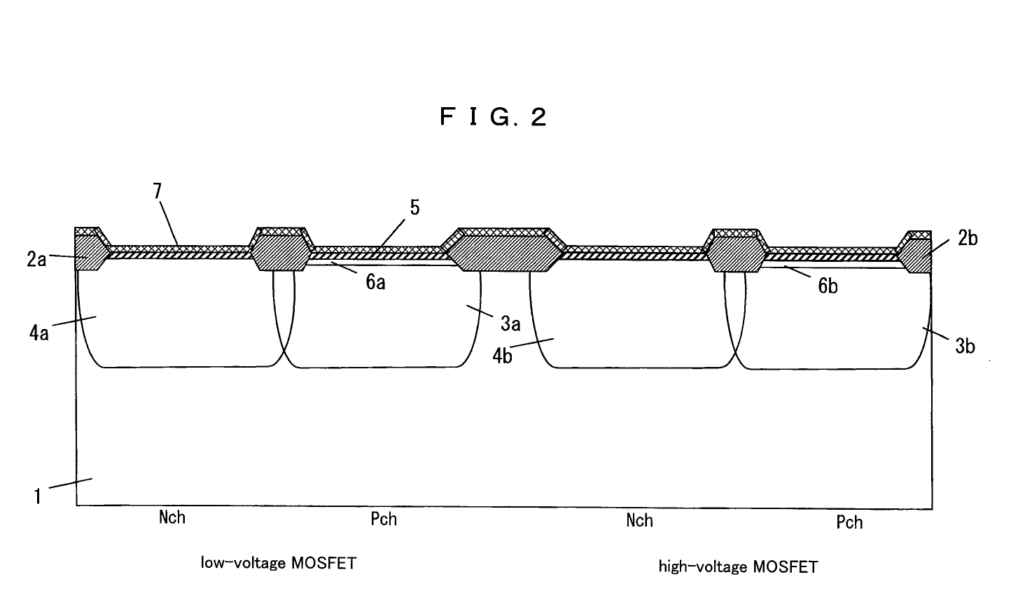

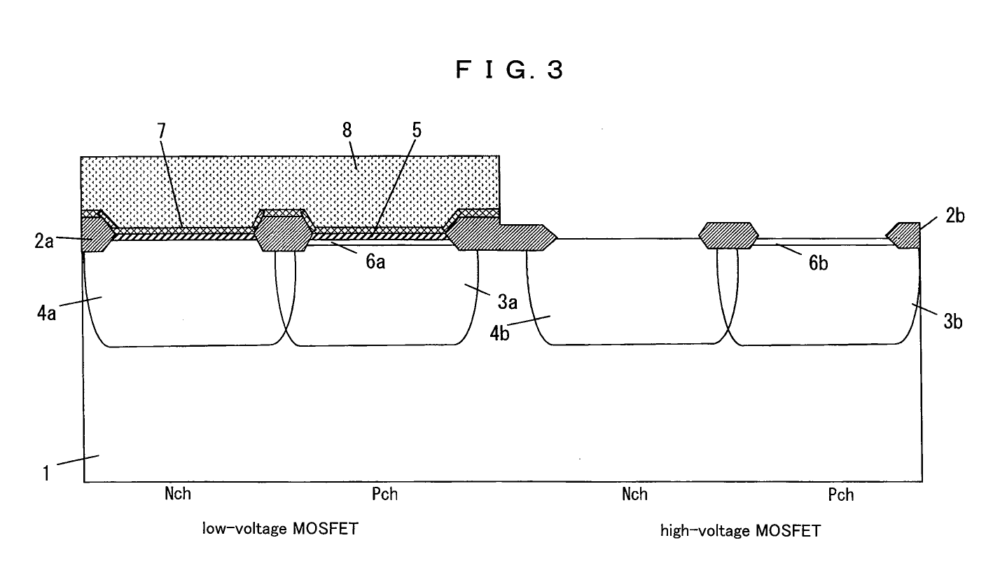

Next, as shown in FIG. 2, a silicon nitride film 7 is grown on the p-type silicon substrate 1. Then, as shown in FIG. 3, a photo resist 8 is applied to the p-type silicon substrate 1, and an opening is formed in the photo resist 8 in the high-voltage MOSFET region. Then, the silicon nitride film 7 is etched, and the silicon oxide film 5 is also etched in such a manner that the photo resist 8 having the opening is used as a mask.

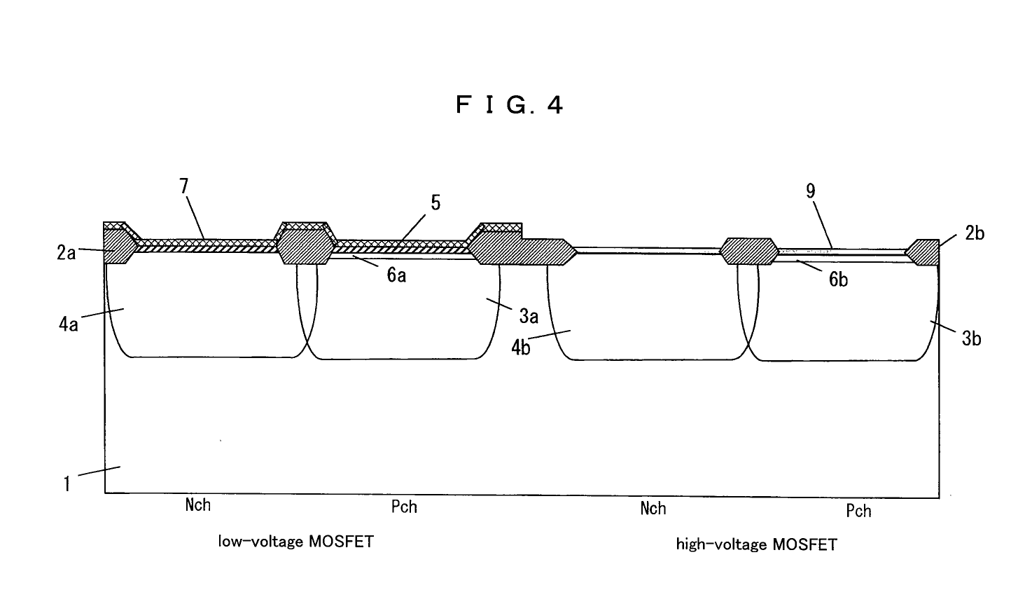

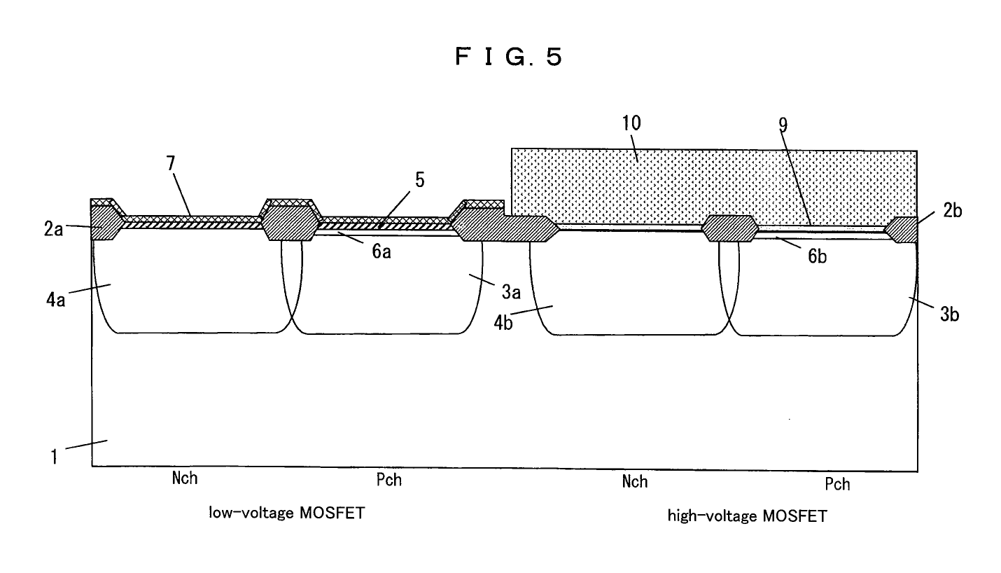

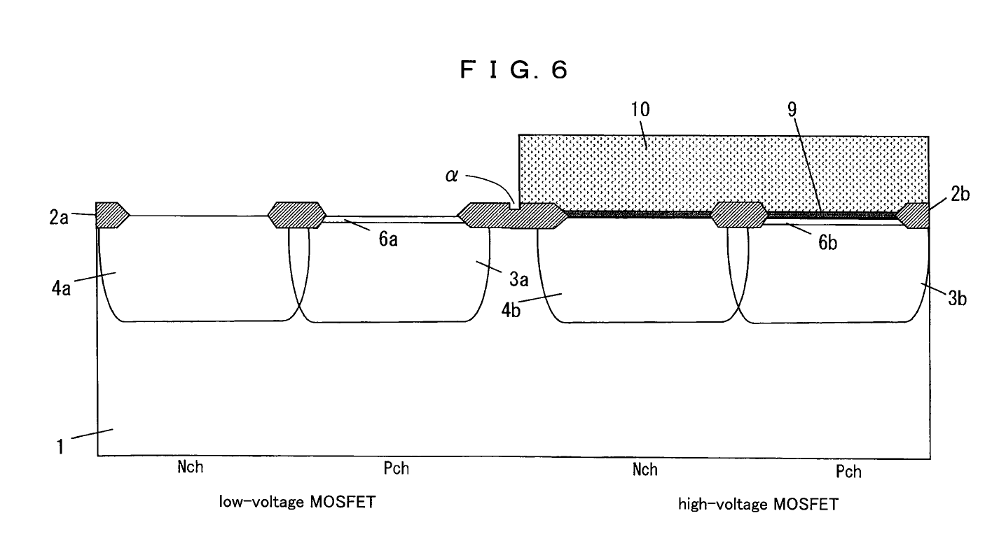

Next, as shown in FIG. 4, the photo resist 8 is removed from the p-type silicon substrate 1, and a gate oxide film (first gate insulation film) 9 for the high-voltage MOSFET is formed on the p-type silicon substrate 1. Then, as shown in FIG. 5, a photo resist 10 is applied to the p-type silicon substrate 1, and an opening is formed in the photo resist 10 in the low-voltage MOSFET region. Further, as shown in FIG. 6, the photo resist 10 having the opening is used as a mask so that the silicon nitride film 7 and the silicon oxide film 5 are etched. The silicon nitride film 7 and the silicon oxide film 5 are similarly etched in the low-voltage MOSFET region and the high-voltage MOSFET region. Therefore, a thickness of the element isolation insulation film in the low-voltage MOSFET region and a thickness of the element isolation insulation film in the high-voltage MOSFET region are equal.

In the present preferred embodiment, there is an overlapping region between the opening formed in the photo resist in the low-voltage MOSFET region and the opening formed in the photo resist in the high-voltage MOSFET region. In the presence of the overlapping region, a recessed section α (see FIG. 6) is formed in the element isolation insulation film provided in a boundary between the low-voltage MOSFET region and the high-voltage MOSFET region, and the silicon nitride film 7 is completely removed including the relevant film formed on the recessed section α. On the contrary, in the case where an interval (gap) is formed between the opening formed in the photo resist in the low-voltage MOSFET region and the opening formed in the photo resist in the high-voltage MOSFET region, the silicon nitride film 7 formed in the gap remains in a protruding shape. Thus, the formation of the overlapping region between the opening formed in the photo resist in the low-voltage MOSFET region and the opening formed in the photo resist in the high-voltage MOSFET region is important in order to remove the silicon nitride film 7. When the silicon oxide film 5 is etched, the wet etching in which BHF is used is adopted.

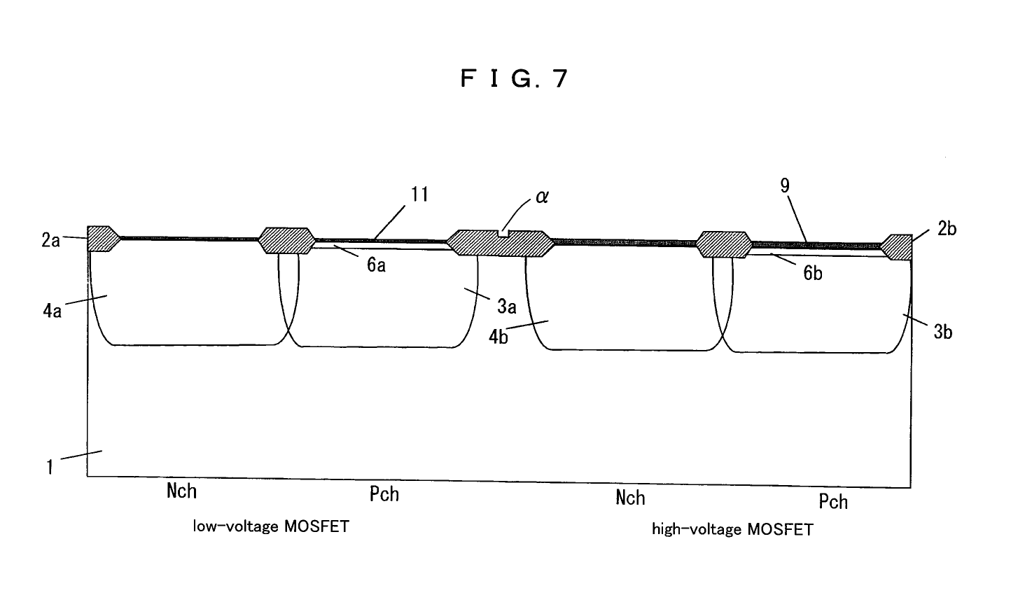

Next, as shown in FIG. 7, a gate oxide film (second gate insulation film) 11 for the low-voltage MOSFET is formed in the low-voltage MOSFET region after the photo resist 10 is removed. At the time, the high-voltage MOSFET region is also oxidized, which increases the thickness of the high-voltage gate oxide film 9. Therefore, the thickness of the high-voltage gate oxide film (first gate insulation film) 9 is larger than that of the low-voltage gate oxide film (second gate insulation film) 11.

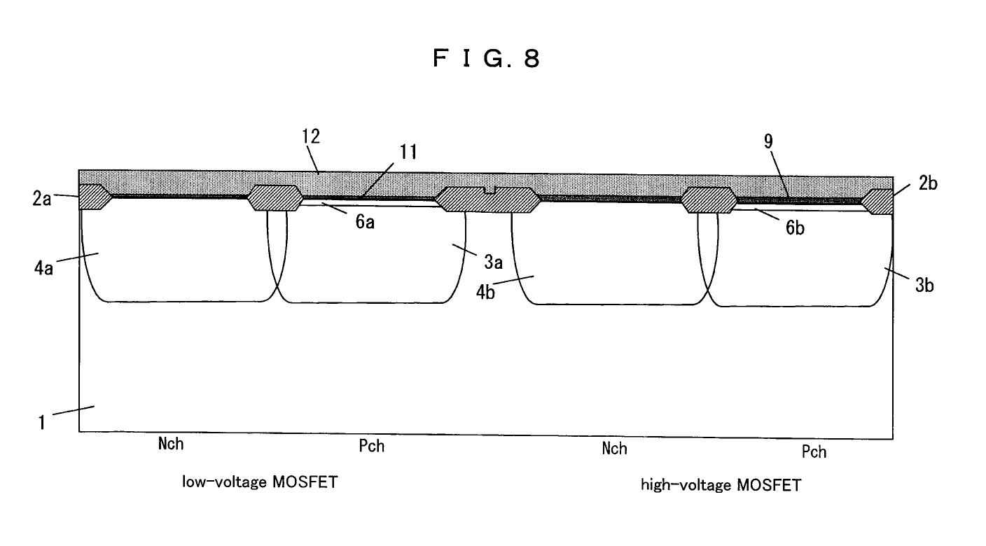

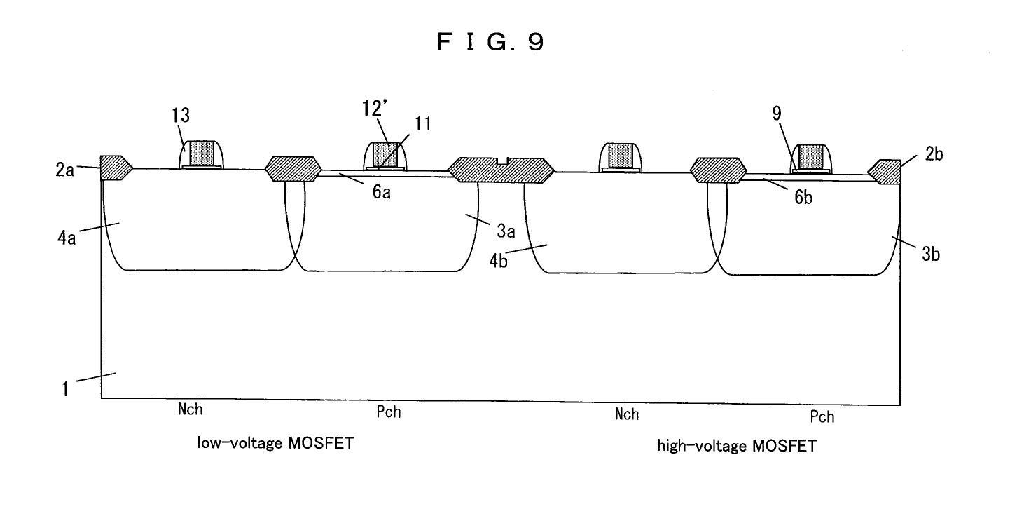

Next, as shown in FIG. 8, an n-type polysilicon film 12 is grown on the p-type silicon substrate 1. Next, as shown in FIG. 9, a photo resist (not shown) is used as the mask so that the n-type silicon film 12 is etched. As a result, polysilicon electrodes 12′ are formed. After that, a lightly-doped drain layer and an offset implanting layer, though not shown, are formed on the p-type silicon substrate 1 so that a side wall 13 is formed on a side surface of each of the polysilicon electrodes 12′.

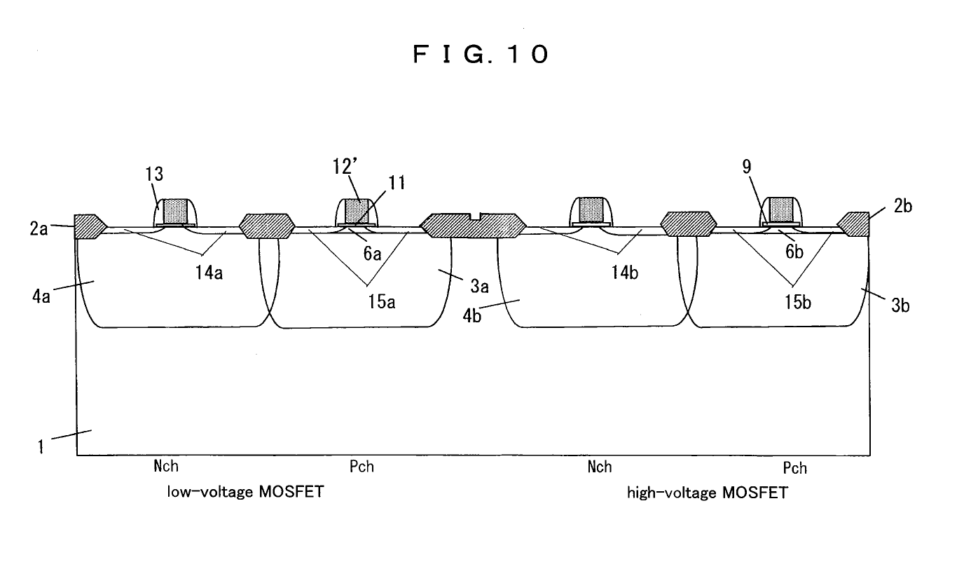

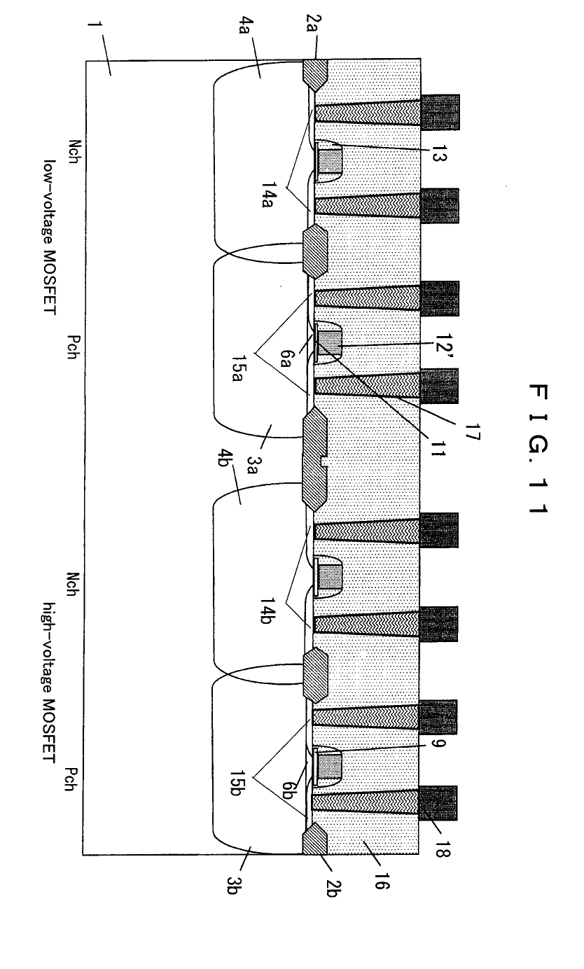

Next, as shown in FIG. 10, a photo resist (not shown) is used as the mask so that gate impurity ions are implanted into the surface of the p-type silicon substrate 1 on both sides of the polysilicon electrodes 12′. After that, a heat treatment is applied to the p-type silicon substrate 1 so that sources and drains 14a and 14b of the n-type MOSFET and sources and drains 15a and 15b of the p-type MOSFET are formed on the p-type silicon substrate 1. Finally, interlayer insulation films 16 (each comprising an oxide silicon film and a BPSG film), W plugs 17 and AL electrodes 18 are formed as shown in FIG. 11.

According to the method of manufacturing the semiconductor device of the present preferred embodiment, the high-voltage gate oxide film 9 is not formed in the low-voltage MOSFET region. Therefore, the surface impurity in the low-voltage MOSFET region is not fetched into the oxide film when the high-voltage gate oxide film is formed. Accordingly, the reduction of the surface impurity concentration can be controlled, and the dose amount for the surface impurity (boron) concentration for controlling the threshold value can be lessened. As a result, it becomes difficult for the surface impurity to go deep (for the impurity to reach a deep section of the p-type silicon substrate 1), and the reduction of the early voltage resulting from the impurity going deep can be thereby controlled. Further, it becomes unnecessary to provide a step of removing the high-voltage gate oxide film 9 with the element isolation insulation film being exposed, which decreases an etching level of the element isolation insulation film. As a result, an isolation breakdown voltage can be favorably improved.

### Modified Embodiment of the Preferred Embodiment 1

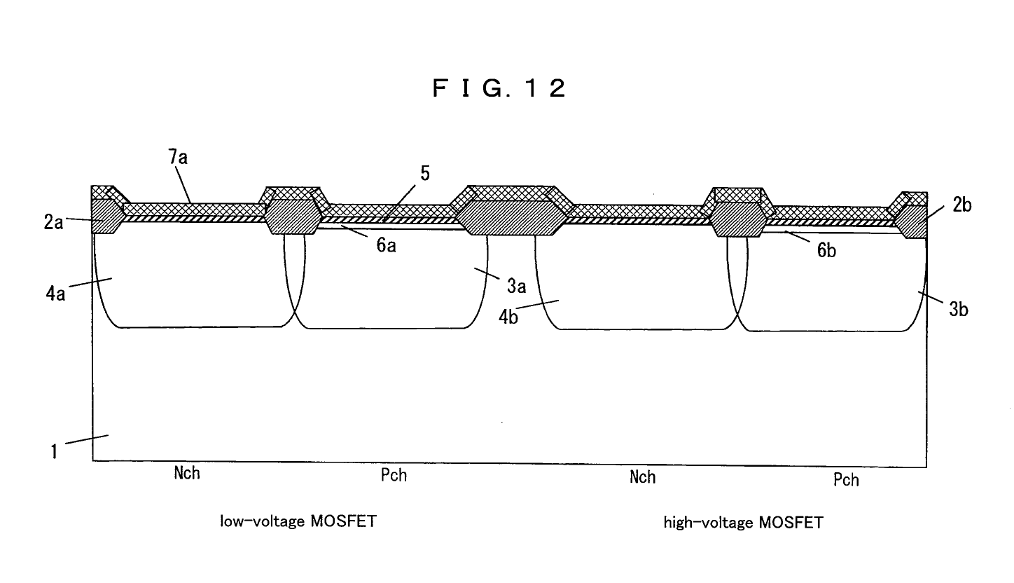

A method of manufacturing a semiconductor device according to a modified embodiment of the preferred embodiment 1 is described referring to FIGS. 8-17. As shown in FIG. 1, the element isolation insulation films 2a and 2b and the silicon oxide film 5 are formed on the p-type silicon substrate 1. Next, the n-type diffusion layers 3a and 3b and the p-type diffusion layers 4a and 4b are formed on the p-type silicon substrate 1, and the p-type diffusion layers 6a and 6b for controlling the surface impurity concentration of the p-type MOSFET are formed on the p-type silicon substrate 1. After that, as shown in FIG. 12, a polysilicon film 7a is grown on the p-type silicon substrate 1.

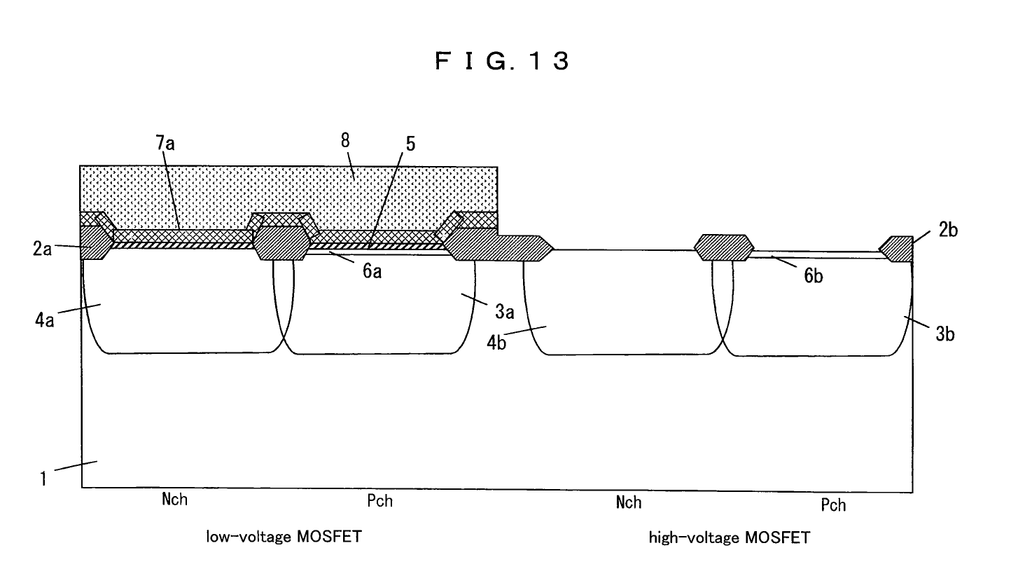

Next, as shown in FIG. 13, the photo resist 8 is applied to the p-type silicon substrate 1, and an opening is formed in the photo resist 8 in the high-voltage MOSFET region. Then, the photo resist 8 having the opening is used as the mask so that the polysilicon film 7a is etched and the silicon oxide film 5 is also etched.

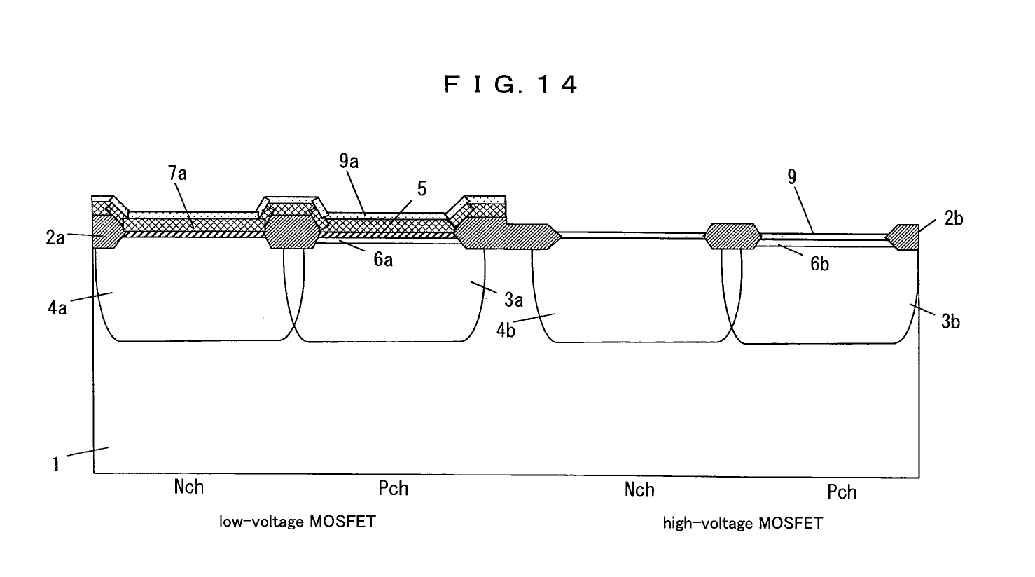

As shown in FIG. 14, the photo resist 8 is removed from the p-type silicon substrate 1, and the high-voltage gate oxide film 9 is thereafter formed on the p-type silicon substrate 1. At the time, an oxide film (silicon oxide film 9a) is formed also on the surface of the low-voltage MOSFET region (polysilicon film 7a). However, in the low-voltage MOSFET region, it is on the polysilicon film 7a that the oxide film is formed. Therefore, a thermal stress applied to the silicon-substrate side when the film 7a is oxidized is smaller than a thermal stress applied to the silicon-substrate side when the silicon nitride film is oxidized.

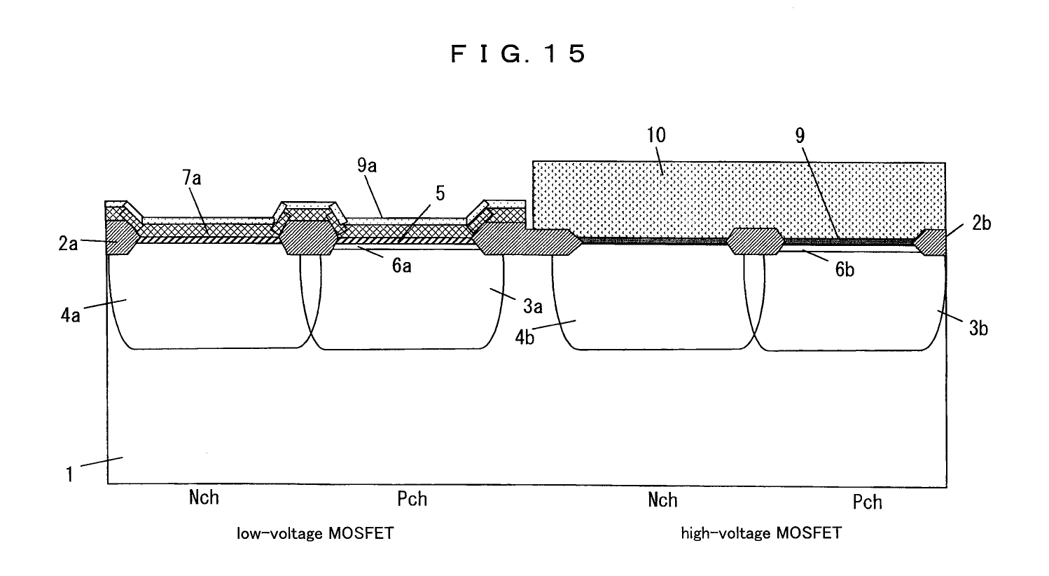

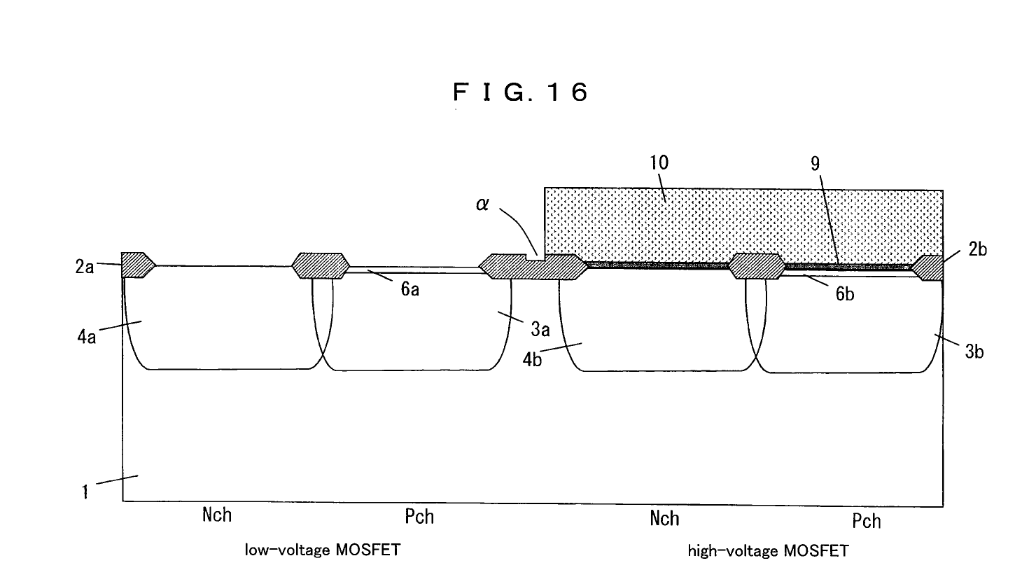

Next, as shown in FIG. 15, the photo resist 10 is applied to the p-type silicon substrate 1, and an opening is thereafter formed in the photo resist 10 in the low-voltage MOSFET region. After that, as shown in FIG. 16, the photo resist 10 having the opening is used as the mask so that the silicon oxide film 9a, polysilicon film 7a and silicon oxide film 5 are etched. When the silicon oxide film 9 and the silicon oxide film 5 are etched, the wet etching process in which BHF is used is adopted, while the dry etching process is adopted when the polysilicon film 7a is etched.

The polysilicon film 7a and the silicon oxide film 5 are etched in the low-voltage MOSFET region and the high-voltage MOSFET region in manners similar to each other. Therefore, the thicknesses of the formed element isolation insulation films are equal in the low-voltage MOSFET region and the high-voltage MOSFET region.

In the present modified embodiment, there is also an overlapping region between the opening formed in the photo resist of the low-voltage MOSFET region and the opening formed in the photo resist of the high-voltage MOSFET region. In the presence of the overlapping region, the recessed section a (see FIG. 6) is formed in the element isolation insulation film provided in the boundary between the low-voltage MOSFET region and the high-voltage MOSFET region, and the silicon nitride film 7 is completely removed including the relevant film formed on the recessed section α. On the contrary, in the case where the interval (gap) is formed between the opening formed in the photo resist in the low-voltage MOSFET region and the opening formed in the photo resist in the high-voltage MOSFET region, the silicon nitride film 7 formed in the gap remains in a protruding shape. Thus, the formation of the overlapping region between the opening formed in the photo resist in the low-voltage MOSFET region and the opening formed in the photo resist in the high-voltage MOSFET region is important in order to remove the silicon nitride film 7.

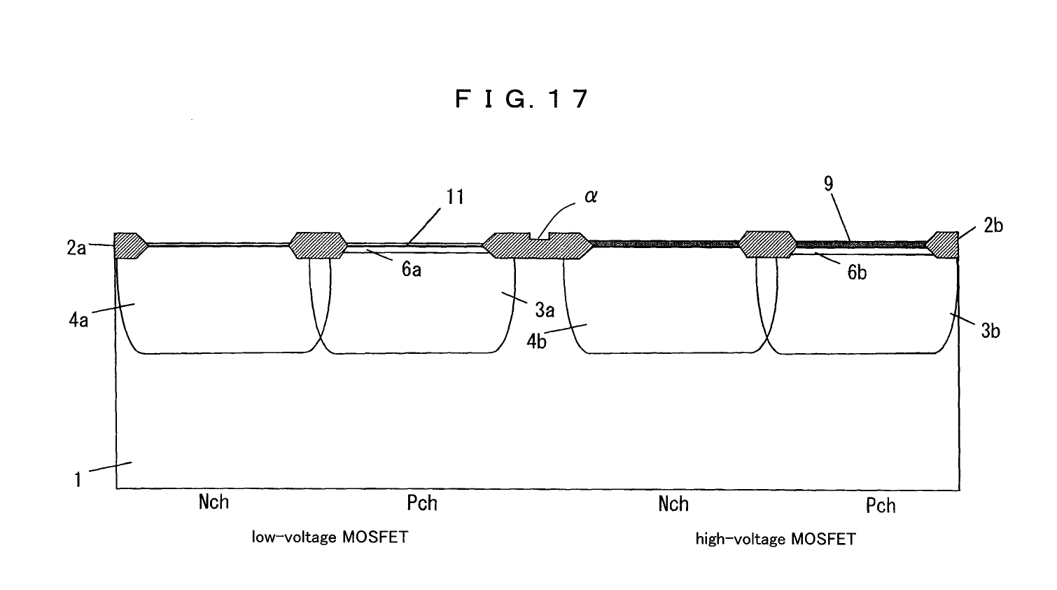

Next, as shown in FIG. 17, the photo resist 10 is removed from the p-type silicon substrate 1, and the low-voltage gate oxide film 11 is thereafter formed in the low-voltage MOSFET region. At the time, the high-voltage MOSFET region is also oxidized, and the thickness of the high-voltage gate oxide film 9 is larger than the thickness of the low-voltage gate oxide film 9.

After that, the n-type polysilicon film 12 is grown on the p-type silicon substrate 1 as shown in FIG. 8 in a manner similar to the preferred embodiment 1. Then, as shown in FIG. 9, a photo resist (not shown) is used as the mask to etch the n-type polysilicon film so that the polysilicon electrodes 12′ are formed on the p-type silicon substrate 1. After that, the lightly-doped drain layer and the offset implantation layer, though not shown, are formed on the p-type silicon substrate 1. As a result, the side wall 13 is formed on the side surface of each of the polysilicon electrodes 12′.

Next, as shown in FIG. 10, a photo resist, not shown, is used as the mask so that the impurity ions are implanted into the p-type silicon substrate 1, and then, the p-type silicon substrate 1 is subjected to a heat treatment. As a result, the sources and the drains 14a and 14b of the n-type MOSFET and the sources and the drains 15a and 15b of the p-type MOSFET are formed on the p-type silicon substrate 1. Finally, the interlayer insulation films 16 (each comprising the oxide silicon film and BPSG film), W plugs 17 and AL electrodes 18 are formed on the p-type silicon substrate 1 as shown in FIG. 11.

According to the method of manufacturing the semiconductor device of the present modified embodiment, in addition to the effect obtained in the preferred embodiment 1, the thermal stress applied to the low-voltage MOSFET region when the high-voltage gate oxide film is formed can be reduced, and the crystallinity of the silicon substrate is not deteriorated. As a result, the MOSFETs which are more stable can be formed.

### Preferred Embodiment 2

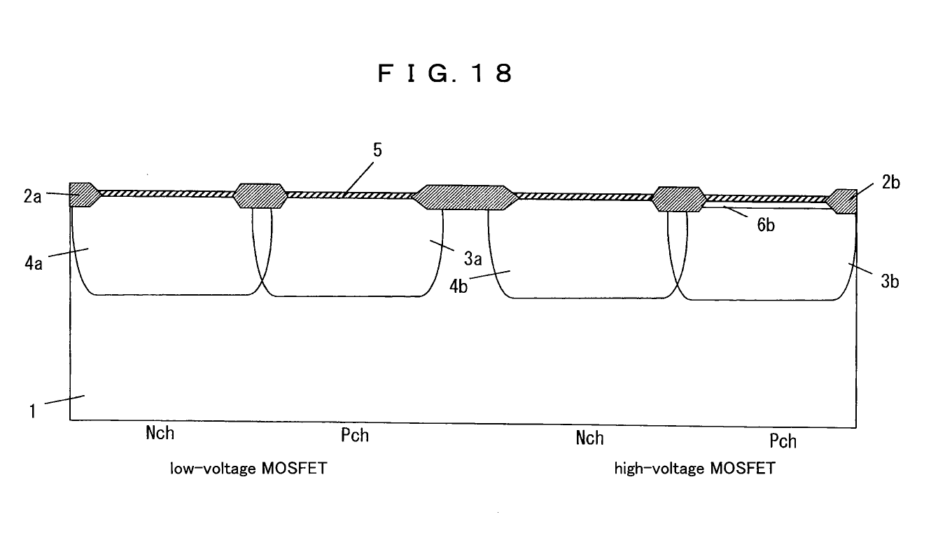

A method of manufacturing a semiconductor device according to a preferred embodiment 2 of the present invention is described referring to FIGS. 18-29. As shown in FIG. 18, the element isolation insulation films 2a and 2b and the silicon oxide film 5 are formed on the p-type silicon substrate 1. Next, the n-type diffusion layers 3a and 3b and the p-type diffusion layers 4a and 4b are formed on the p-type silicon substrate 1, and further, the p-type diffusion layer 6b for controlling the surface impurity concentration of the p-type MOSFET is formed.

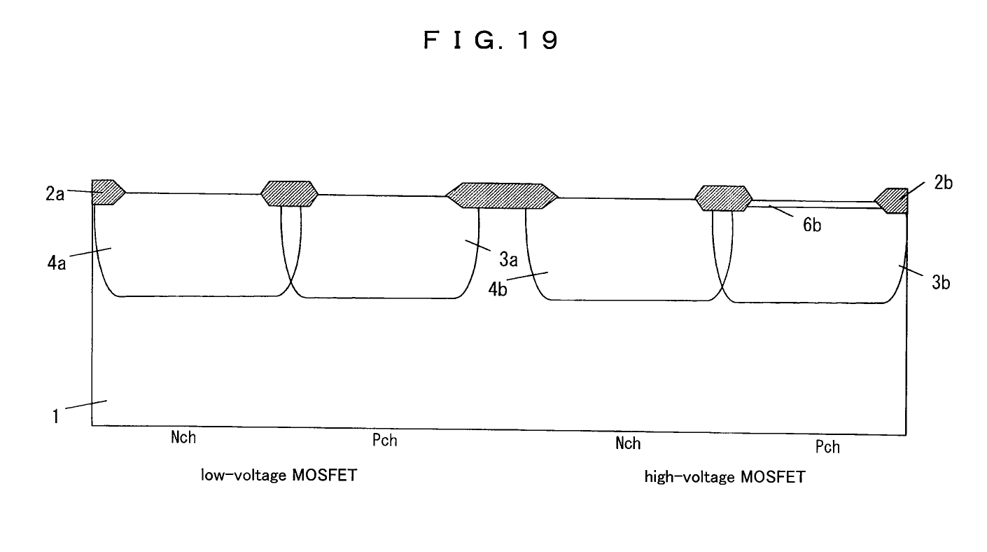

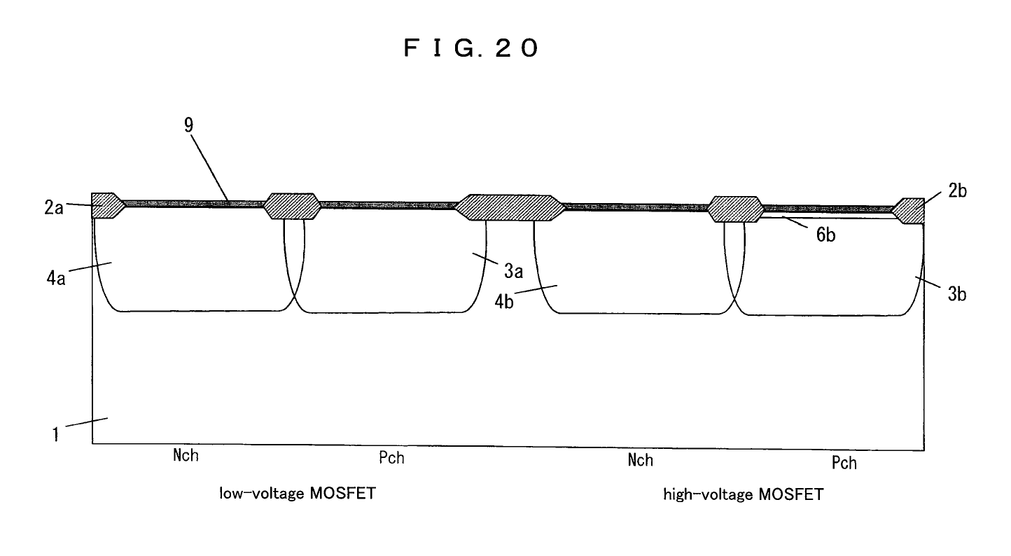

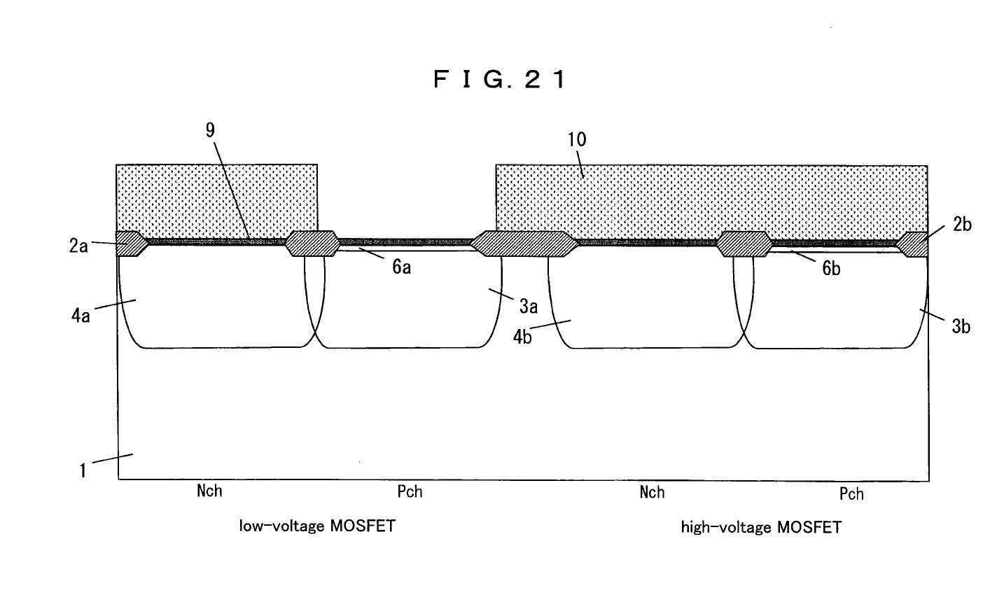

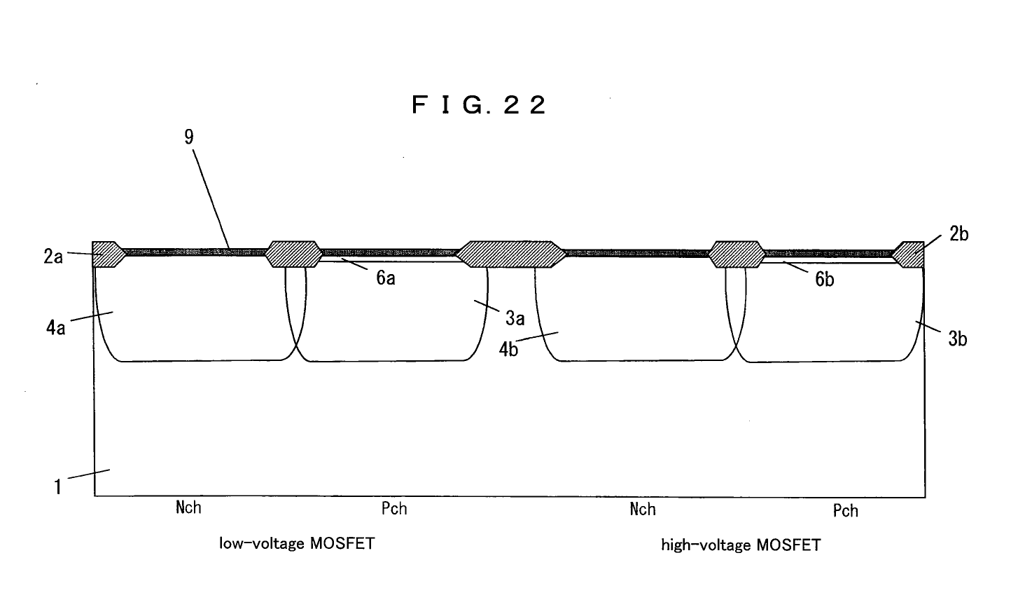

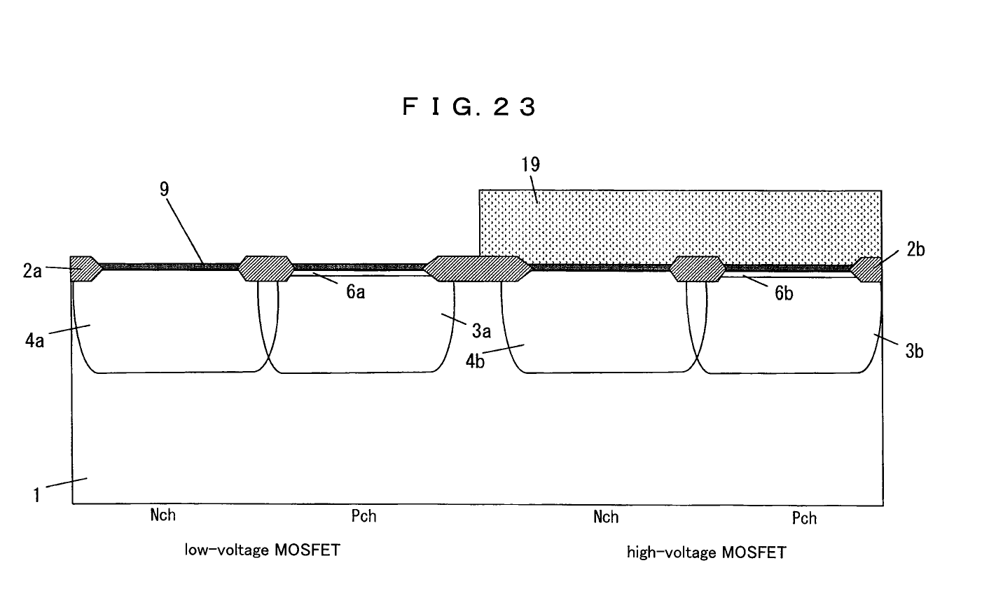

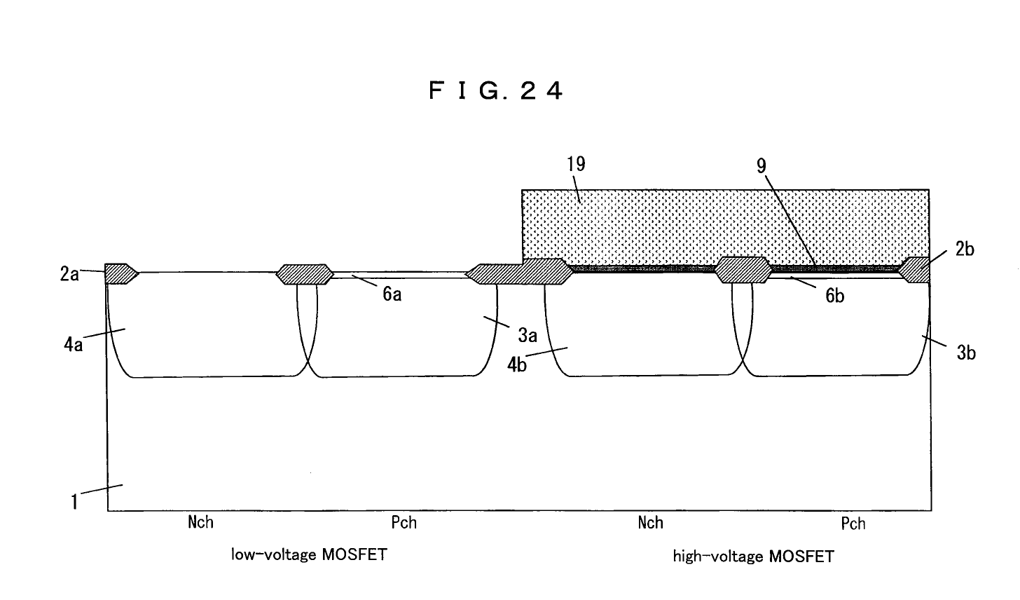

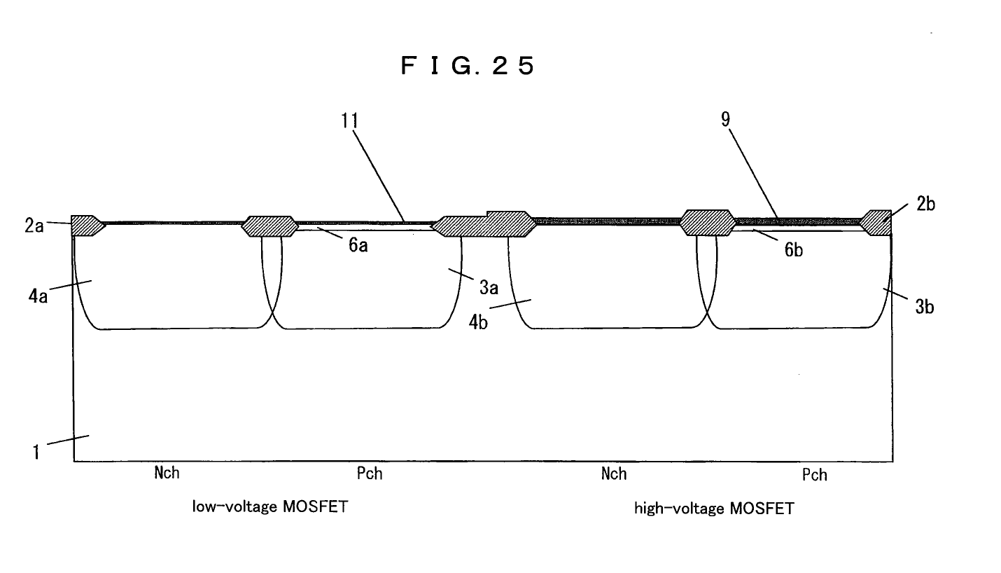

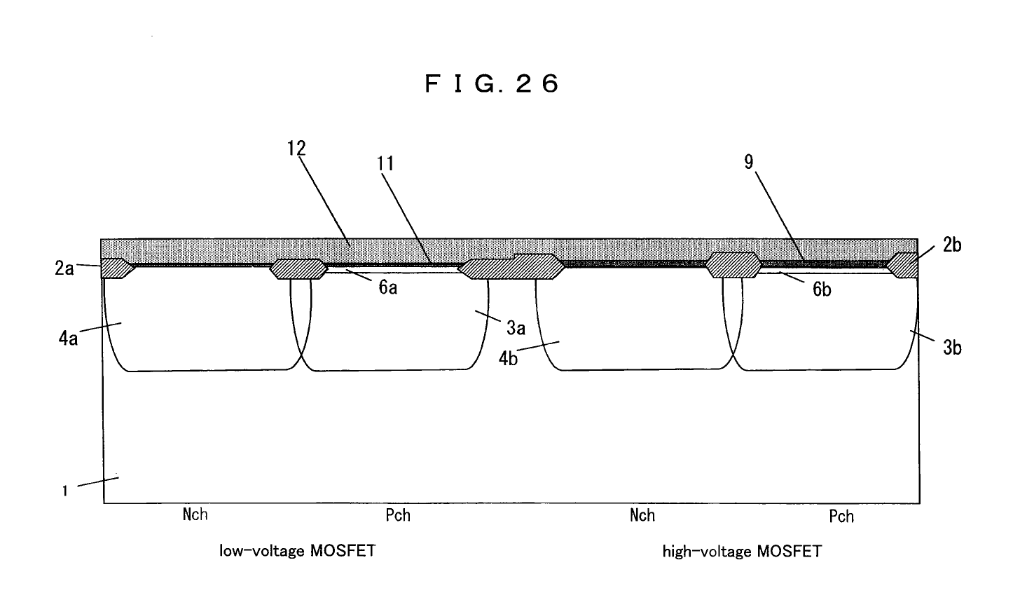

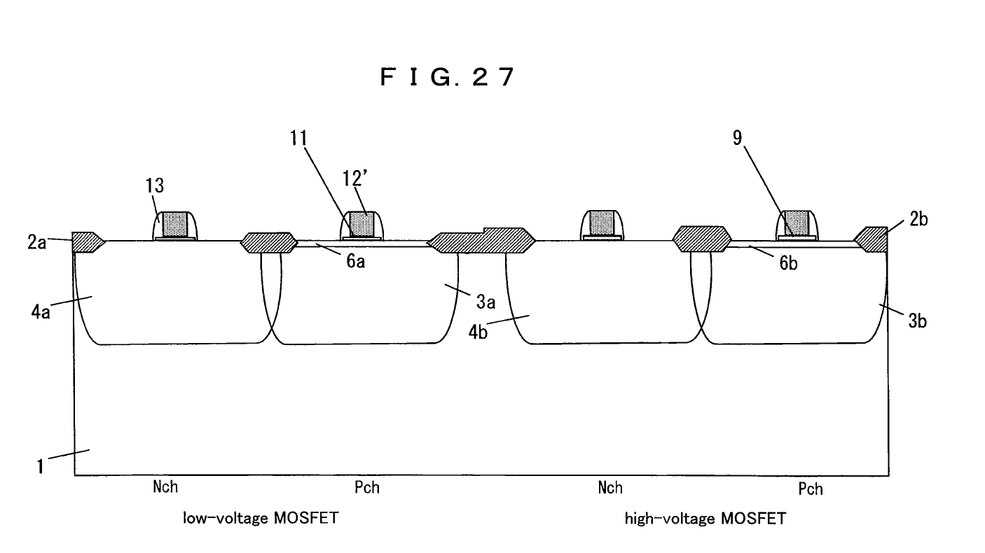

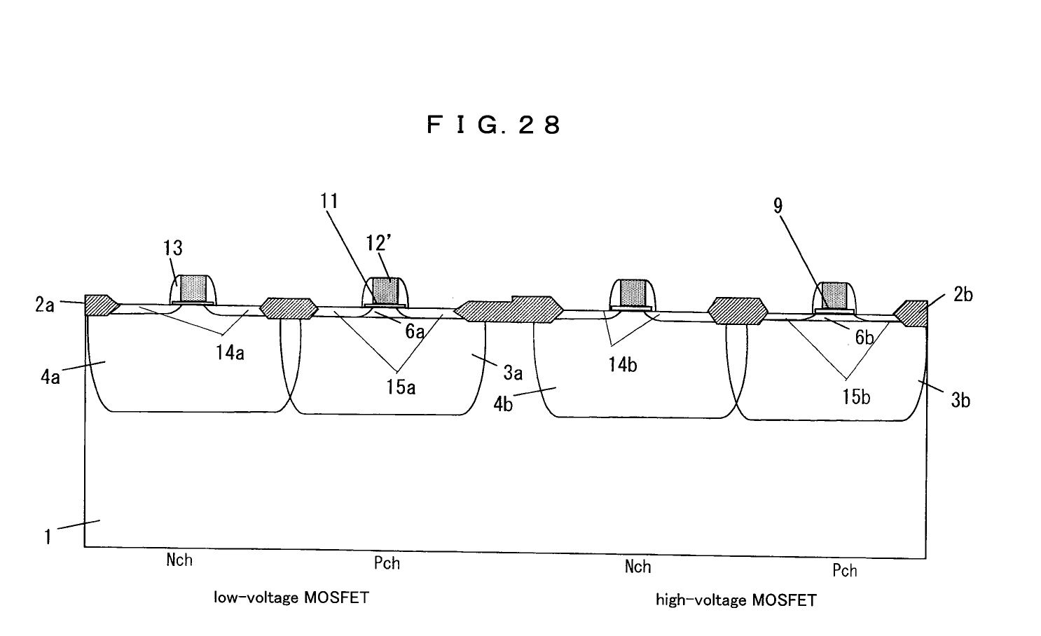

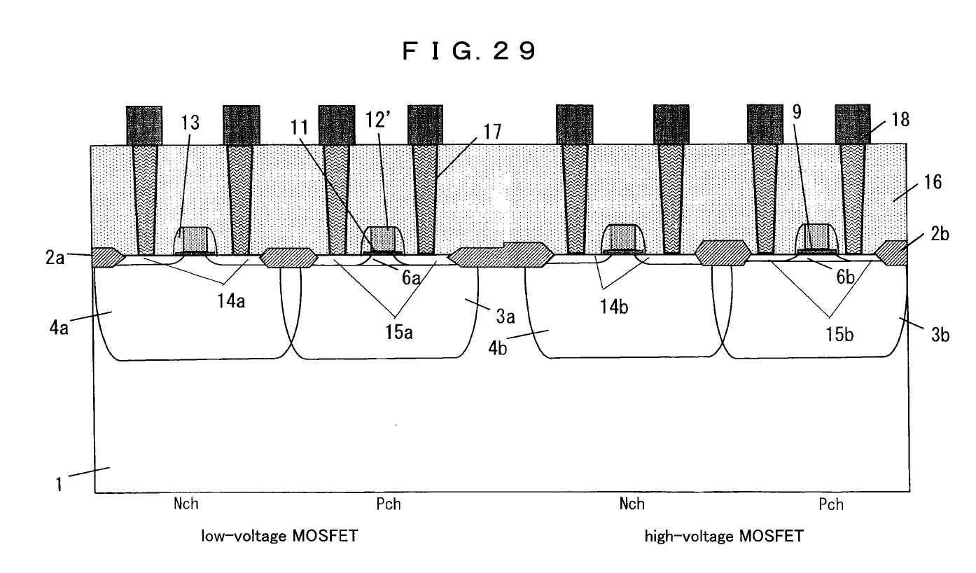

Next, as shown in FIG. 19, the silicon oxide film 5 is etched and removed. After that, as shown in FIG. 20, the high-voltage gate oxide film 9 is formed on the p-type silicon substrate 1. Next, as shown in FIG. 21, the photo resist 10 is applied to the p-type silicon substrate 1, and then, an opening is formed in the photoresist 10 in the low-voltage p-type MOSFET region. Then, the photo resist 10 having the opening is used as the mask to implant the boron ions for controlling the threshold value into the p-type silicon substrate 1 so that the p-type diffusion layer 6a is formed on the p-type silicon substrate 1. Next, as shown in FIG. 22, the photo resist 10 is removed from the p-type silicon substrate 1. After that, as shown in FIG. 23, a photo resist 19 is applied to the p-type silicon substrate 1 again. Then, an opening is formed in the photo resist 19 in the low-voltage MOSFET region, and the photo resist 19 having the opening is used as the mask so that the high-voltage gate oxide film 9 is etched as shown in FIG. 24. As shown in FIG. 25, the photo resist 19 is then removed from the p-type silicon substrate 1. After that, the low-voltage gate oxide film 11 is formed on the p-type silicon substrate 1, and the n-type polysilicon film 12 is grown on the p-type silicon substrate 1 as shown in FIG. 26. Then, as shown in FIG. 27, a photo resist, not shown, is used as the mask to etch the n-type polysilicon film 12 so that the polysilicon electrodes 12′ are formed. After that, the side wall film 13 is formed on the side surface of each of the polysilicon electrodes 12′. Next, as shown in FIG. 28, a photo resist, not shown, is used as the mask so that the impurity ions are implanted into the p-type silicon substrate 1, and a heat treatment is thereafter applied thereto. As a result, the sources and the drains 14a and 14b of the n-type MOSFET and the sources and the drains 15a and 15b of the p-type MOSFET are formed on the p-type silicon substrate 1. Finally, the interlayer insulation films 16 (each comprising the oxide silicon film and BPSG film), W plugs 17 and AL electrodes 18 are formed as shown in FIG. 29.

According to the method of manufacturing the semiconductor device of the present preferred embodiment, the ions for controlling the threshold voltage in the low-voltage MOSFET are implanted after the high-voltage gate oxide film 9 is formed. Accordingly, the impurity for controlling the threshold voltage in the low-voltage p-type MOSFET is not fetched into the high-voltage gate oxide film. As a result, the reduction of the impurity for controlling the threshold voltage in the low-voltage p-type MOSFET is prevented, and the dose amount for the surface impurity (boron) concentration for controlling the threshold value can be lessened. Then, the reduction of the early voltage resulting from the surface impurity going deep can be controlled.

### Preferred Embodiment 3

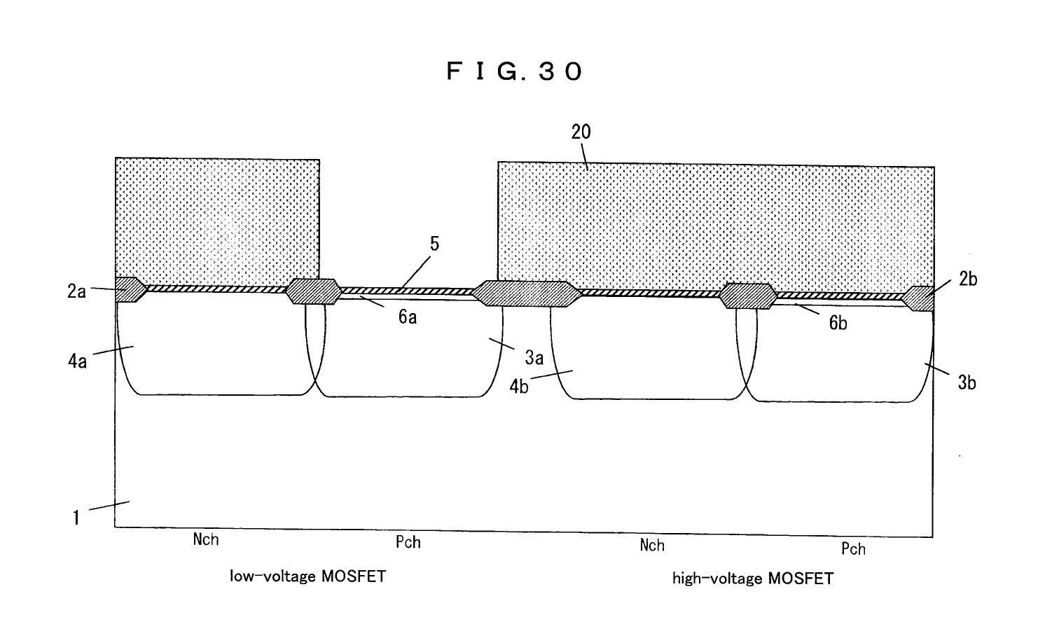

A method of manufacturing a semiconductor device according to a preferred embodiment 3 of the present invention is described referring to FIGS. 30-40. As shown in FIG. 30, the element isolation insulation films 2a and 2b and the silicon oxide film 5 are formed on the p-type silicon substrate 1. Then, a photo resist 20 is applied to the p-type silicon substrate 1, and an opening is formed in the photo resist 20 in the low-voltage p-type MOSFET region (first element region). After that, the photo resist 20 having the opening is used as the mask so that phosphorous ions are implanted into the p-type silicon substrate 1 in multiple stages at approximately 700 keV, 300 keV and 150 keV, and arsenic ions are implanted into the p-type silicon substrate 1 at approximately 250 keV. Then, the n-type diffusion layer 3a is formed on the p-type silicon substrate 1.

Below is described a shape of the n-type diffusion layer 3a along the depth direction (substrate-thickness direction). The phosphorous ions (second impurity of the second conductive type) are implanted in multiple stages at approximately 700 keV and 300 keV so that a retrograde well is formed at a deep section, in a thickness direction, of the low-voltage p-type MOSFET region. The phosphorous ions (second impurity of the second conductive type) are implanted at approximately 150 keV so that an enhanced dope layer is formed at an intermediate section, in a thickness direction, of the low-voltage p-type MOSFET region. The arsenic ions (third impurity of the second conductive type) are implanted at approximately 250 keV so that a punch-through control (barrier) layer is formed at a surface section of the low-voltage p-type MOSFET region.

Subsequent to that, the boron ions (impurity of the first conductive type) for controlling the surface impurity concentration of the low-voltage p-type MOSFET are implanted into the p-type silicon substrate 1 at approximately 5 keV so that the p-type diffusion layer (channel dope layer) 6a is formed on the p-type silicon substrate 1.

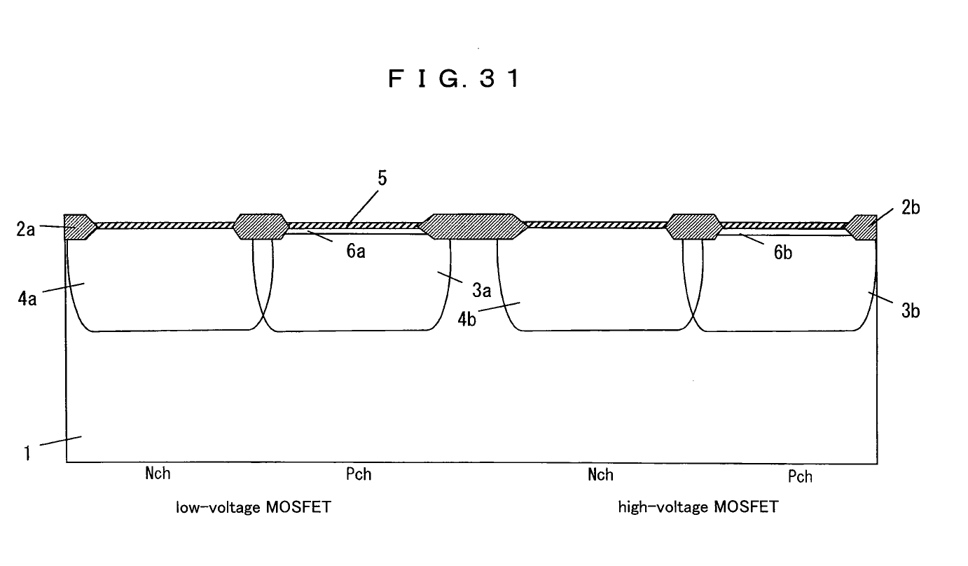

As shown in FIG. 31, the photo resist 20 is removed from the p-type silicon substrate 1. After that, the n-type diffusion layer 3b is formed in the high-voltage p-type MOSFET region (second element region) so that the p-type diffusion layers 4a and 4b are respectively formed in the low-voltage n-type MOSFET region and the high-voltage n-type MOSFET region.

Below is described a shape of the n-type diffusion layer 3b along the depth direction (substrate-thickness direction). The phosphorous ions are implanted into the high-voltage p-type MOSFET region (second element region) in multiple stages at approximately 700 keV and 300 keV so that a retrograde well is formed at a deep section, in a thickness direction, of the high-voltage p-type MOSFET region. The arsenic ions are implanted into the high-voltage p-type MOSFET region (second element region) at approximately 250 keV so that a punch-through control layer is formed at a surface section of the high-voltage p-type MOSFET region.

Next are described shapes of the p-type diffusion layers 4a and 4b along the depth direction. The boron ions are implanted into the p-type MOSFET regions in multiple stages at approximately 400 keV and 150 keV so that a retrograde well and a channel stopper layer are formed in the respective p-type MOSFET regions. The retrograde well is formed at deep sections, in a thickness direction, of the p-type MOSFET regions. The boron ions are implanted at approximately 30 keV so that the impurity concentrations of the surface sections of the p-type diffusion layers 4a and 4b are adjusted. Then, the boron ions for controlling the surface impurity concentration of the high-voltage p-type MOSFET are implanted into the p-type MOSFET regions at approximately 5 keV so that the p-type diffusion layer 6b is formed on the surface sections of the p-type diffusion layers 4a and 4b.

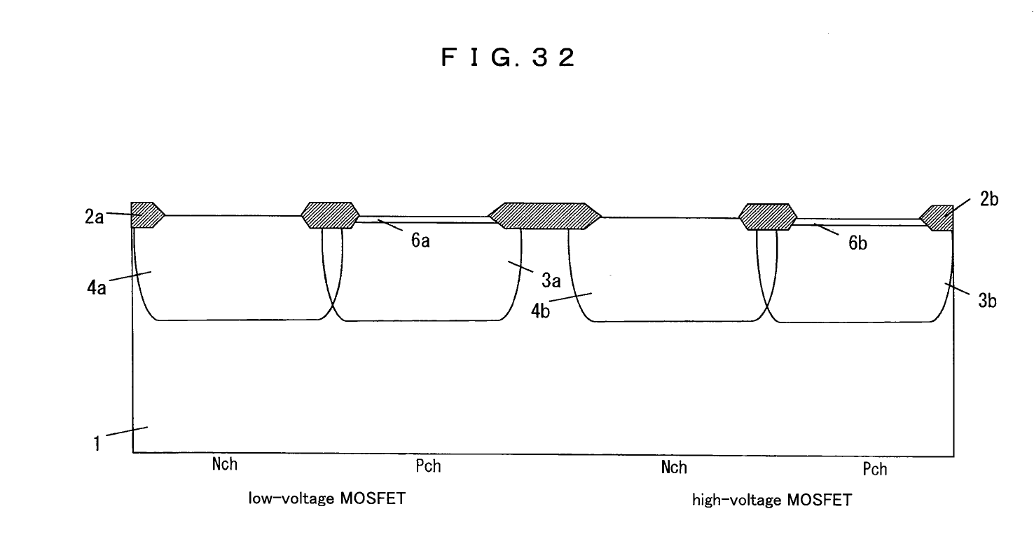

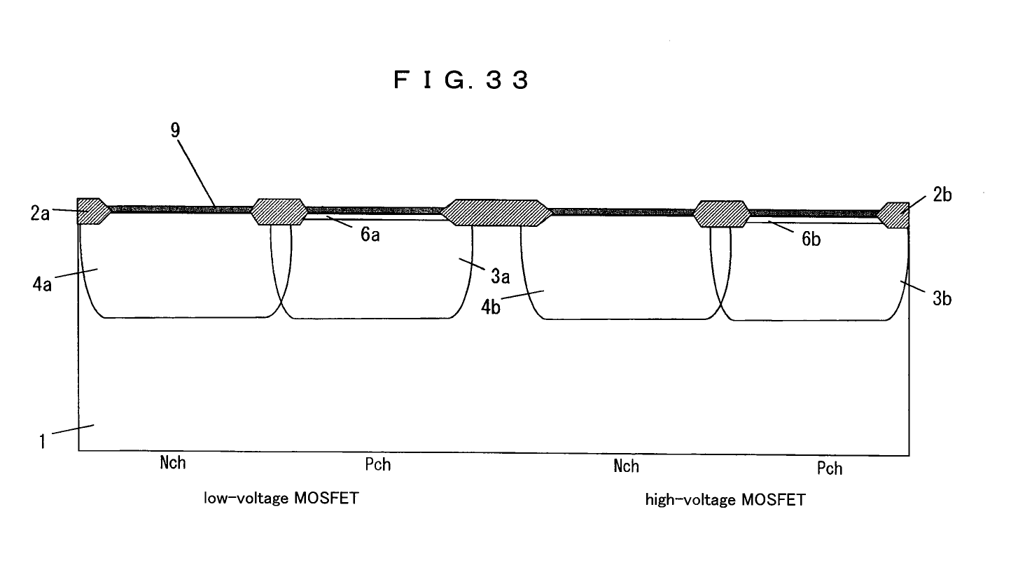

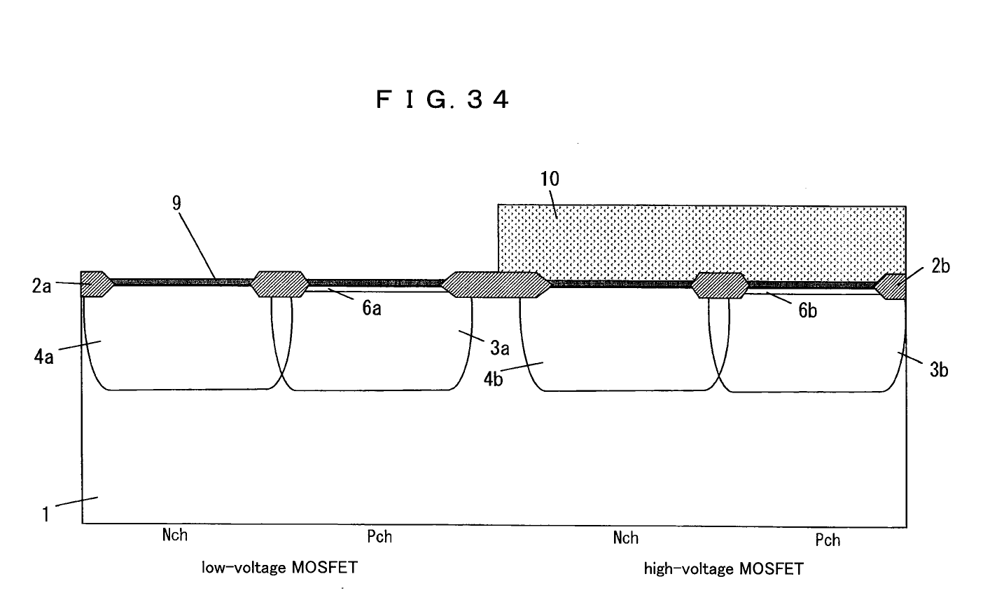

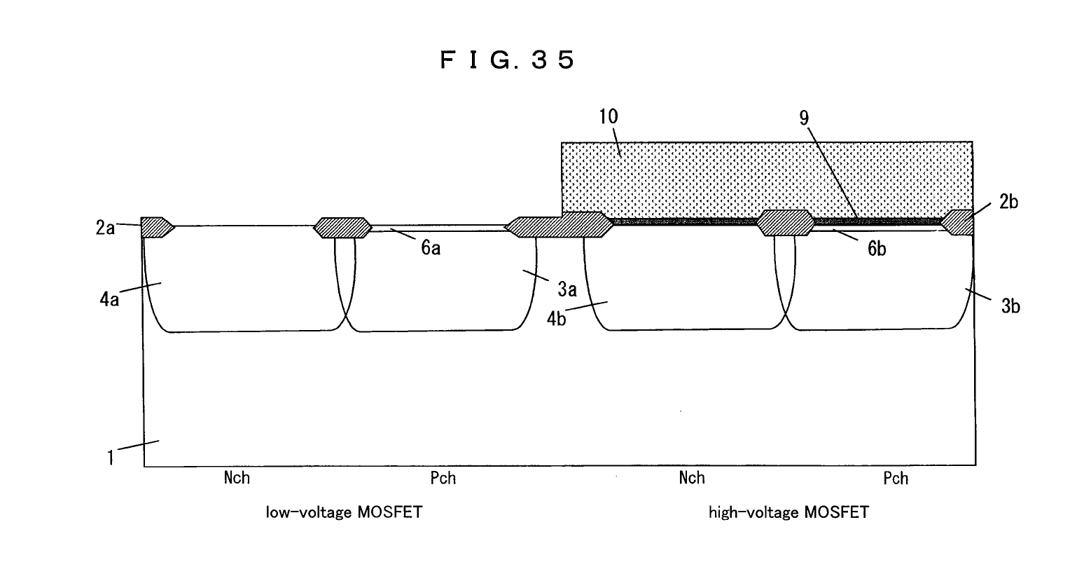

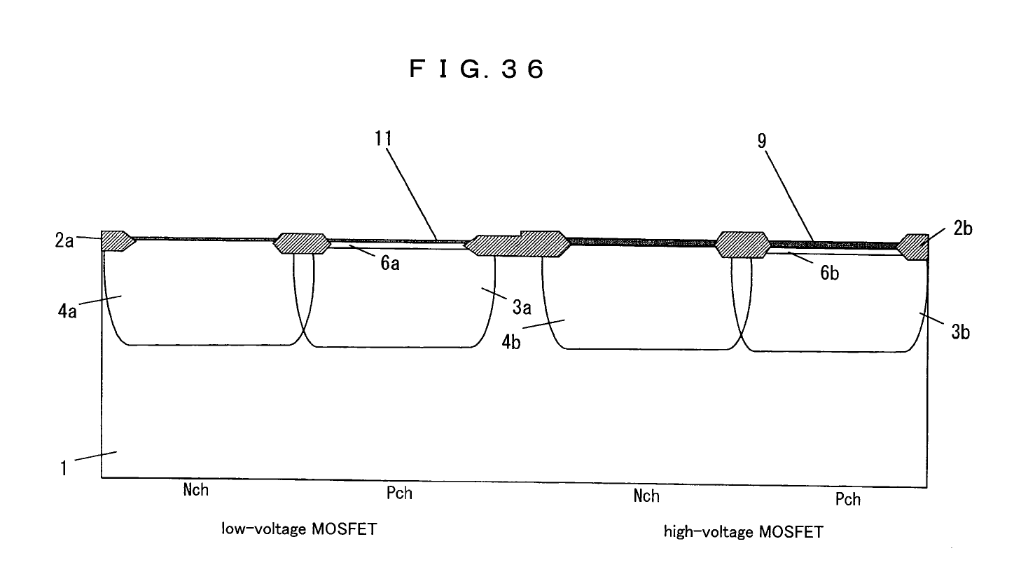

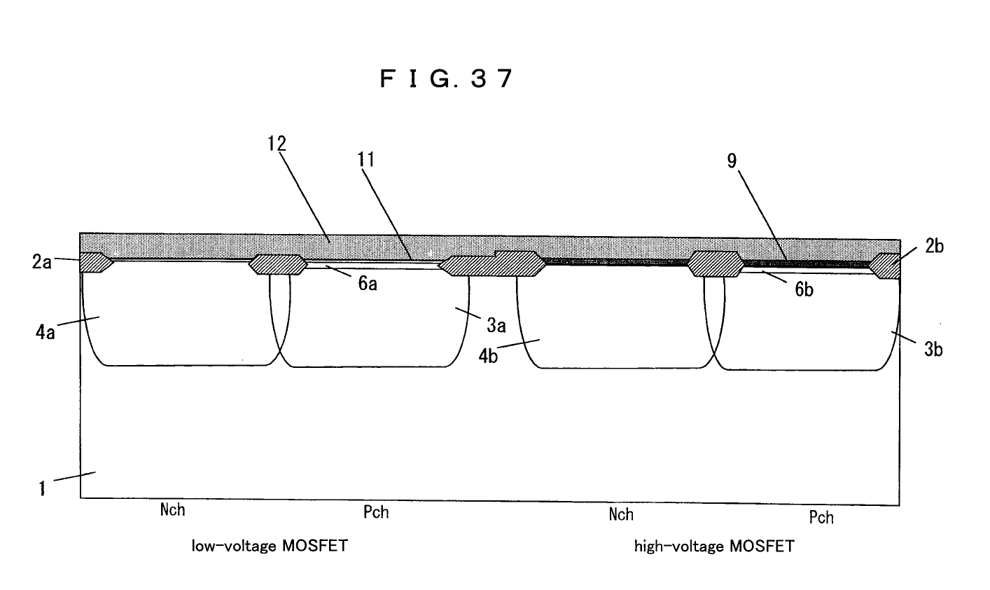

Next, as shown in FIG. 33, the high-voltage gate oxide film 9 is formed on the p-type silicon substrate 1 after the silicon oxide film 5 is etched as shown in FIG. 32. Then, as shown in FIG. 34, the photo resist 10 is applied to the p-type silicon substrate 1. After that, an opening is formed in the photo resist 10 in the low-voltage MOSFET region, and the photo resist 10 having the opening is used as the mask so that the high-voltage gate oxide film 9 is etched as shown in FIG. 35. Then, as shown in FIG. 36, the photo resist 10 is removed, and the low-voltage gate oxide film 11 is thereafter formed in the low-voltage MOSFET region. The high-voltage MOSFET region is also oxidized at the time, and the high-voltage gate oxide film 9 becomes thicker than the low-voltage gate oxide film 11. Then, the n-type polysilicon film 12 is grown on the p-type silicon substrate 1 as shown in FIG. 37.

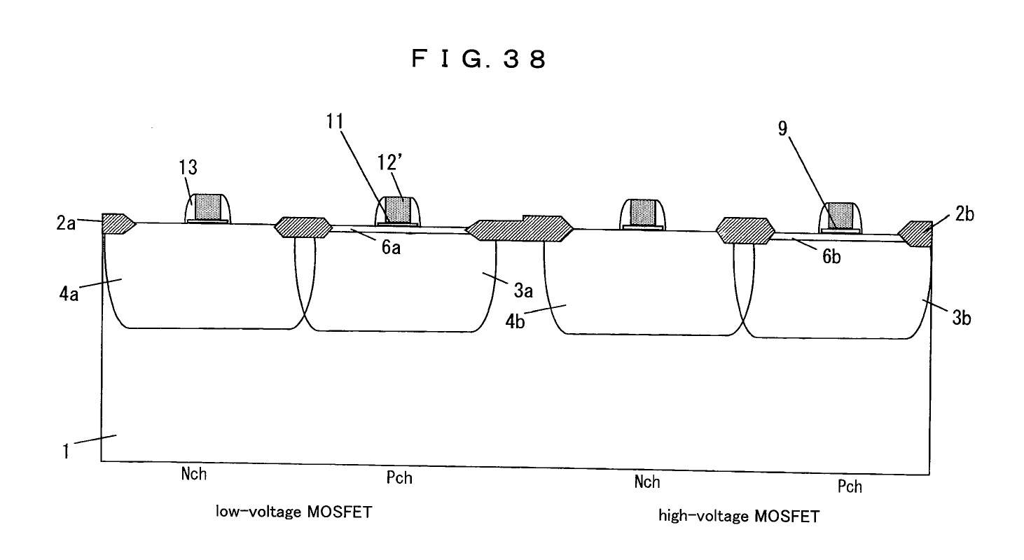

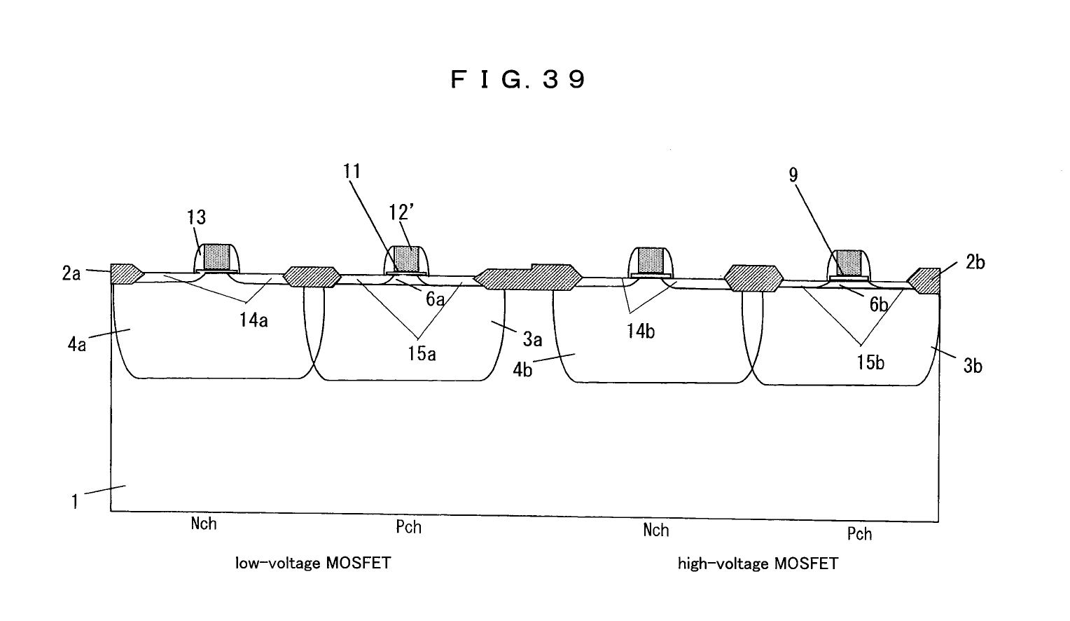

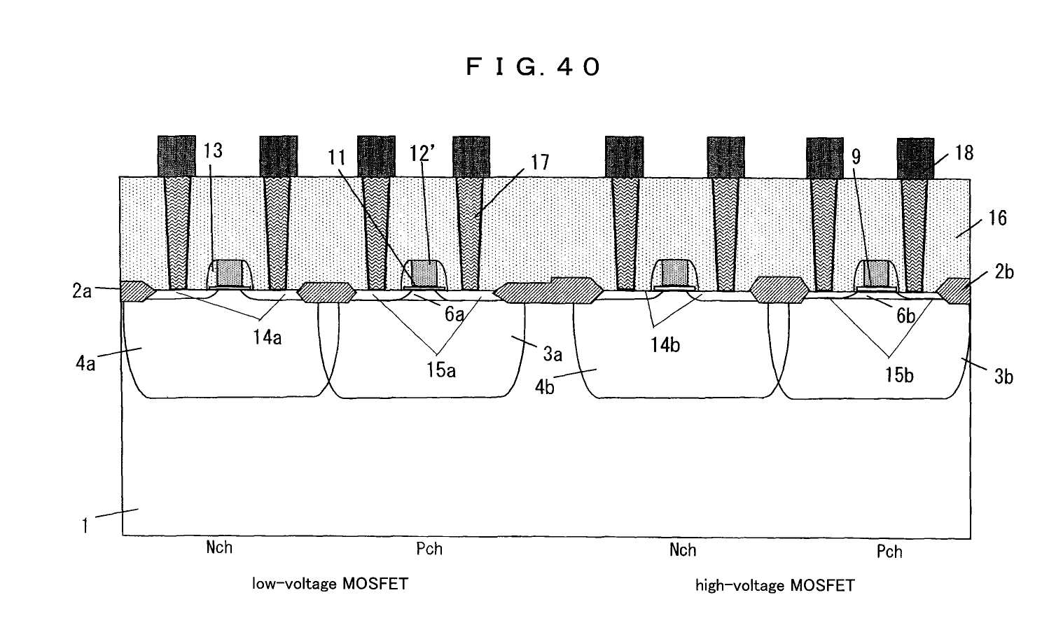

As shown in FIG. 38, a photo resist, not shown, is used as the mask to etch the n-type polysilicon film 12 so that the polysilicon electrodes 12′ are formed. After that, the side wall film 13 is formed on the side surface of each of the polysilicon electrodes 12′, and the impurity ions are implanted into the p-type silicon substrate 1 with a photo resist, not shown, being used as the mask as shown in FIG. 39. Then, the p-type silicon substrate 1 is heat-treated so that the sources and the drains 14a and 14b of the n-type MOSFET and the sources and the drains 15a and 15b of the p-type MOSFET are formed on the p-type silicon substrate 1. Finally, the interlayer insulation films 16 (each comprising the oxide silicon film and BPSG film), W plugs 17 and AL electrodes 18 are formed as shown in FIG. 40.

According to the method of manufacturing the semiconductor device of the present preferred embodiment, the shapes along the depth direction (substrate-thickness direction) of the low-voltage p-type MOSFET region are as follows. The enhanced dope layer is formed at the intermediate section on the border between the punch-through control layer at the surface section of the low-voltage p-type MOSFET region and the retrograde well at the deep section thereof. The respective layers including the enhanced dope layer are formed in such a manner that three impurity profiles are distributed on the p-type silicon substrate 1 through the ion implantation. More specifically, the phosphorous profile constituting the retrograde well (first impurity of the second conductive type) is distributed at the deep section of the low-voltage p-type MOSFET region, the arsenic profile constituting the punch-through control layer (third impurity of the second conductive type) is distributed at the surface section of the low-voltage p-type MOSFET region, and the phosphorous profile constituting the enhanced dope layer (second impurity of the second conductive type) is distributed in the region where the retrograde well and the punch-through control layer intersect with each other.

At an intermediate section of the n-type diffusion layer 3a in the substrate-thickness direction is formed an intersecting section having a low n-type impurity concentration. In the present preferred embodiment, the phosphor of the enhanced dope layer is selectively implanted into the vicinity of the intersecting section so that the impurity concentration is increased. Therefore, the amount of the implanted n-type impurity with respect to the surface section of the n-type diffusion layer 3a can be reduced, as a result of which the increase of the surface p-type impurity concentration for controlling the threshold value is controlled, while the n-type impurity concentration on the bulk side can be increased at the same time. As a result, the reduction of the early voltage can be controlled.

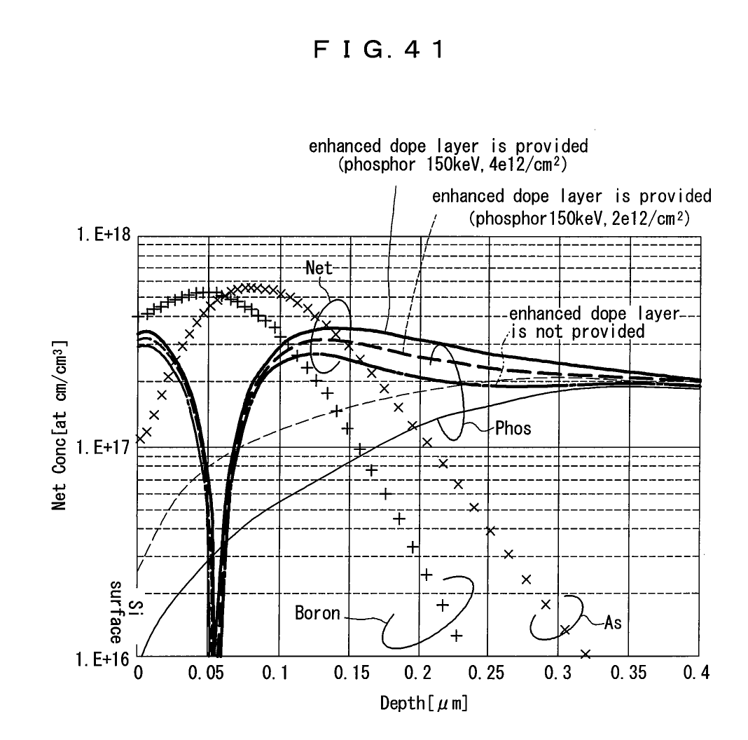

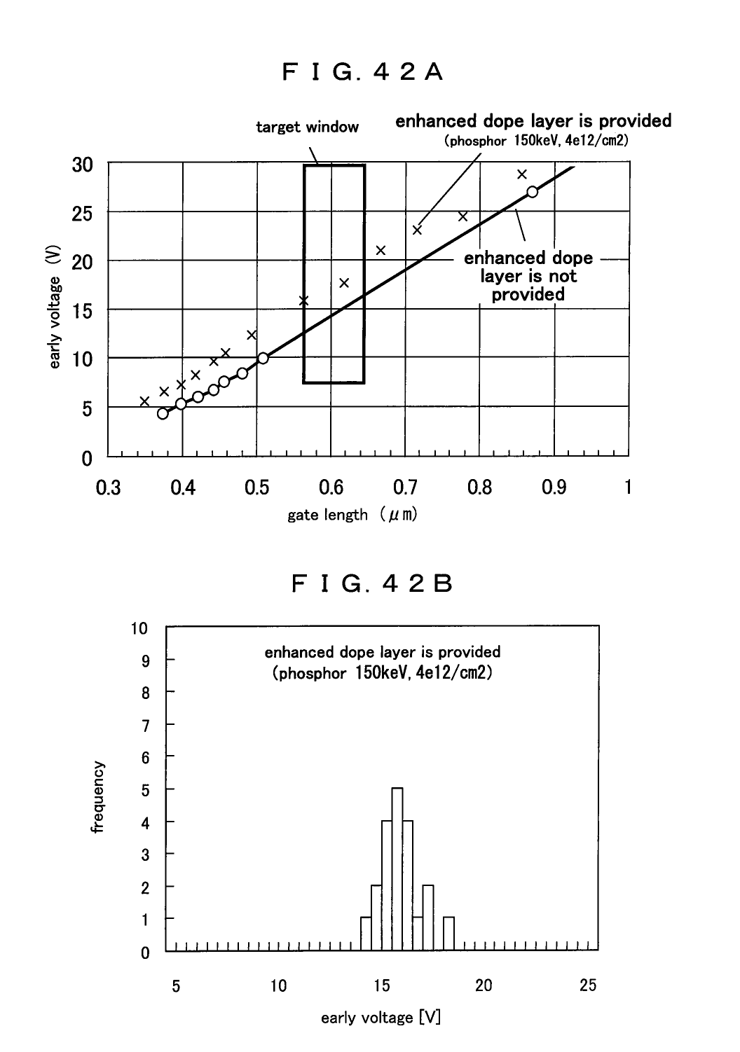

The semiconductor device according to the preferred embodiment 3 is described referring to FIGS. 41, 42A and 42B. An example of the constitution of the semiconductor device is shown in FIG. 40. FIG. 41 is a depth profile of the impurity amount immediately below the gate electrode of the low-voltage p-type MOSFET. The retrograde well by the phosphor implantation and the punch-through control layer by the arsenic implantation are formed on the p-type silicon substrate 1. The enhanced dope layer by the phosphor implantation is formed in a region approximately 0.2 μm deep from the surface of the substrate, where the retrograde well and the punch-through control layer intersect with each other. Therefore, the n-type impurity concentration in the region approximately 0.2 μm deep from the surface of the substrate is increased. Accordingly, the increase of the p-type impurity (boron) concentration for controlling the threshold voltage is controlled, while the n-type impurity (phosphor) concentration on the bulk side is increased at the same time. As a result, the reduction of the early voltage can be controlled. The enhanced dope layer can be formed, not only through the phosphor implantation, but also through the arsenic implantation.

FIG. 42A is a characteristic chart of the early voltage of the low-voltage p-type MOSFET according to the present invention having the impurity profile shown in FIG. 41. As is clear from FIG. 42A, the enhanced dope layer provided in the region where the retrograde well and the punch-through control layer intersect with each other prevents a depletion layer from extending toward the well, which controls the reduction of the early voltage. Therefore, in the constitution according to the present invention comprising the enhanced dope layer, for example, the early voltage increases by approximately 4V in the vicinity of the gate length of 0.6 μm in comparison to the conventional constitution in which the enhanced dope layer is not provided.

Further, as shown in FIG. 42B, in the constitution according to the present invention, the early voltage can be substantially distributed in such a voltage range as 15-19 V in the low-voltage p-type MOSFET having the gate length of 0.56 μm. As a result, an analog circuit comprising a low-voltage MOSFET superior in analog characteristic can be realized in the semiconductor device provided with low-voltage and high-voltage MOSFETs.

According to the semiconductor device of the present preferred embodiment and the method of manufacturing the same, wherein the amount of the implanted n-type impurity in the vicinity of the surface is reduced in the low-voltage p-type MOSFET, the increase of the surface impurity concentration for controlling the threshold value is controlled, while the impurity concentration on the bulk side can be increased at the same time. As a result, the reduction of the early voltage can be controlled.

According to the method of manufacturing the semiconductor device of the present preferred embodiment, the n-type diffusion layers 3a and 3b are formed in the separate steps; however, may be formed as follows. After the retrograde well and the punch-through control layer, which are commonly used in the low-voltage p-type MOSFET region and the high-voltage p-type MOSFET region, are formed in the same step, the enhanced dope layer is formed only in the low-voltage p-type MOSFET region. Accordingly, the number of the steps for implanting the ions can be reduced. The channel dope layer, which can be commonly used in the low-voltage p-type MOSFET region and the high-voltage p-type MOSFET region, may be similarly formed in the same step.

In place of the formation of the enhanced dope layer only in the low-voltage p-type MOSFET region, the enhanced dope layer may be formed in the high-voltage p-type MOSFET region simultaneously when it is formed in the low-voltage p-type MOSFET region. As a result, the process of forming the n-type diffusion layers 3a and 3b can be simplified.

While there has been described what is at present considered to be preferred embodiments of this invention, it will be understood that various modifications may be made therein, and it is intended to cover in the appended claims all such modifications as fall within the true spirit and scope of this invention.

What is claimed is:

1. A semiconductor device comprising at least two MOSFETs each comprising a gate insulation film having a thickness different to each other, further comprising:
a semiconductor substrate of a first conductive type;
a first element region and a second element region provided on the semiconductor substrate;
a retrograde well formed from a first impurity of a second conductive type and provided at a deep section, in a thickness direction, of the first element region;
an enhanced dope layer formed from a second impurity of the second conductive type and provided at an intermediate section, in a thickness direction, of the first element region;
a punch-through control layer formed from a third impurity of the second conductive type and provided at a surface section of the first element region;
a second gate insulation film provided on the semiconductor substrate and making contact with the first element region; and
a first gate insulation film provided on the semiconductor substrate, making contact with the second element region and having a thickness larger than a thickness of the second gate insulation film, wherein
the second impurity is distributed in a region where a profile of the first impurity and a profile of the third impurity intersect with each other.

2. The semiconductor device as claimed in claim 1, further comprising:
an isolation insulation film provided on the semiconductor substrate and surrounding the first and second element regions;
a first gate electrode provided on the semiconductor substrate and making contact with the first gate insulation film; and
a second gate electrode provided on the semiconductor substrate and contacting the second gate insulation film.

3. The semiconductor device as claimed in claim 1, further comprising a channel dope layer formed from a fourth impurity of the first conductive type, provided on the semiconductor substrate and making contact with the first element region, wherein
the first element region constitutes a p-type MOSFET of an embedding channel type.

4. The semiconductor device as claimed in claim 3, wherein
the first and second impurities are phosphor,
the third impurity is arsenic, and
the fourth impurity is boron.

5. A method of manufacturing a semiconductor device comprising at least two MOSFETs each comprising a gate insulation film having a thickness different to each other, including:
a step of forming a first element region and a second element region on a semiconductor substrate of a first conductive type;
a step of ion-implanting a first impurity of a second conductive type at a deep section, in a thickness direction, of the first element region, a second impurity of the second conductive type at an intermediate section, in a thickness direction, of the first element region, and a third impurity of the second conductive type at a surface section of the first element region;
a step of forming a first gate insulation film on the semiconductor substrate including the first and second element regions after the first through third impurities are ion-implanted;
a step of selectively removing the first gate insulation film from the first element region and thereafter selectively forming a second insulation film in the first element region; and
a step of forming a gate electrode on the respective first and second gate insulation films, wherein
the first through third impurities are ion-implanted so that the second impurity is distributed in a region where a profile of the first impurity and a profile of the third impurity intersect with each other.

6. The method of manufacturing the semiconductor device as claimed in claim 5, wherein
an element isolation insulation film is formed on the semiconductor substrate, and the first and second element regions are thereafter formed on the semiconductor substrate in a state that they are surrounded by the element isolation insulation film.

7. The method of manufacturing the semiconductor device as claimed in claim 5, further including a step of ion-implanting a fourth impurity of the first conductive type at a surface section of the first element region, wherein
a p-type MOSFET of an embedding channel type is formed in the first element region.

8. The method of manufacturing the semiconductor device as claimed in claim 7, wherein
the first through third impurities are ion-implanted so that a peak position of the first impurity is deeper than a peak position of the third impurity in a depth direction of the first element region and a peak position of the second impurity is between the peak positions of the first and third impurities in the depth direction of the first element region, and
the fourth impurity is ion-implanted so that a peak position of the fourth impurity is shallower than the peak position of the third impurity in the depth direction of the first element region.

9. A method of manufacturing a semiconductor device comprising at least two MOSFETs each comprising a gate insulation film having a thickness different to each other, including:
a step of forming a first element region and a second element region on a semiconductor substrate of a first conductive type;
a step of ion-implanting an impurity of a second conductive type inside the first element region and an impurity of the first conductive type at a surface section of the first element region;
a step of selectively forming a first gate insulation film in the second element region and a second gate insulation film in the first element region after the impurities are ion-implanted; and
a step of forming a gate electrode on the respective first and second gate insulation films, wherein
a p-type MOSFET of an embedding channel type is formed in the first element region.

10. The method of manufacturing the semiconductor device as claimed in claim 9, wherein
an element isolation insulation film is formed on the semiconductor substrate, and the first and second element regions are thereafter formed on the semiconductor substrate in a state that they are surrounded by the element isolation insulation film.

11. The method of manufacturing the semiconductor device as claimed in claim 9, wherein
the step of selectively forming the first gate insulation film includes:
a step of selectively forming a silicon nitride film in the respective first and second element regions;
a step of selectively removing the silicon nitride film formed in the second element region; and
a step of selectively forming the first gate insulation film in the second element region and thereafter selectively removing the silicon nitride film formed in the first element region.

12. The method of manufacturing the semiconductor device as claimed in claim 9, wherein
the step of selectively forming the first gate insulation film includes:
a step of selectively forming a polysilicon film in the respective first and second element regions;
a step of selectively removing the polysilicon film formed in the second element region; and
a step of selectively forming the first gate insulation film in the second element region and thereafter selectively removing the polysilicon film formed in the first element region.

13. The method of manufacturing the semiconductor device as claimed in claim 9, wherein
the step of selectively forming the first gate insulation film includes:
a step of selectively forming the first gate insulation film in the respective first and second element regions; and
a step of selectively removing the first gate insulation film formed in the first element region, wherein
the step of forming the first gate insulation film is implemented before the impurity of the first conductive type is ion-implanted.
